(19) United States
(12) Patent Application Publication
(10) Pub. No.: US 2021/0332290 A1
(43) Pub. Date: Oct. 28, 2021

(54) ORGANIC LIGHT-EMITTING MATERIAL BASED ON A PLATINUM TETRADENTATE ONCN COMPLEX, PREPARATION METHOD AND APPLICATION THEREOF IN ORGANIC LIGHT-EMITTING DIODES

(71) Applicant: GUANGDONG AGLAIA OPTOELECTRONIC MATERIALS CO., LTD, Foshan, Guangdong (CN)

(72) Inventors: Jiahuan PENG, Foshan (CN); Huiyang LI, Foshan (CN); Lei DAI, Foshan (CN); Lifei CAI, Foshan (CN)

(73) Assignee: GUANGDONG AGLAIA OPTOELECTRONIC MATERIALS CO., LTD, Foshan, Guangdong (CN)

(21) Appl. No.: 17/271,939

(22) PCT Filed: Jul. 25, 2019
(86) PCT No.: PCT/CN2019/097642

§ 371 Date: Feb. 26, 2021

(30) Foreign Application Priority Data
Sep. 3, 2018 (CN) 201811018445.7

(51) Int. Cl. C09K 11/06; H01L 51/00

(52) U.S. Cl. CPC C09K 11/06; H01L 51/5016; H01L 51/0087

(57) ABSTRACT

The present invention relates to an organic light-emitting material based on a platinum tetradentate ONCN complex, a preparation method and application thereof in organic light-emitting diodes, A platinum (II) tetradentate ONCN complex light-emitting material having the chemical structure of Formula I can be used for manufacturing organic light emitting diodes with pure greenemission. The material has been optimized in structure and has better anti-aggregation ability compared with the reported platinum (II) tetradentate ONCN complex light-emitting material. The emission spectrum of the material only slightly changes or even remains unchanged at high doping concentration, so the organic light-emitting diode made of this material obviously has higher emission efficiency. The preparation method for the complex light-emitting material is simple and does not require the use of highly toxic and harmful reagents, and is more suitable for industrial preparation systems.

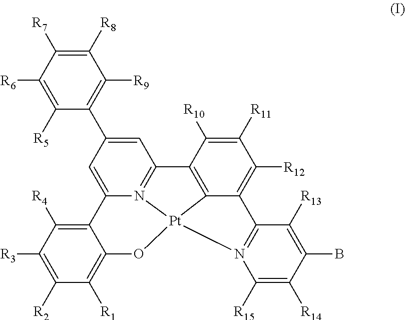

### TECHNICAL FIELD OF THE INVENTION

The present invention relates to a class of organic metal materials with optimized structures, and the applications thereof in organic light-emitting diodes (OLED) and polymer light-emitting diodes (PLED). High-efficiency monochromatic OLEDs can be manufactured by a variety of technologies including vacuum deposition, spin coating, or printing, using organic metal materials showing better emission quantum efficiency and better color purity.

### DESCRIPTION OF THE PRIOR ART

OLED is namely an organic light-emitting diode or an organic light-emitting device. OLED is an independent light-emitting device without backlight, with characteristics such as fast response speed, low driving voltage, high light-emitting efficiency, high resolution, and wide viewing angle, so it has already become a new generation of display and lighting technologies, especially with huge application prospects in mobile phones, computers, TVs, bendable and foldable electronic products.

There are currently two types of light-emitting materials used in OLEDs: fluorescent materials and phosphorescent materials. The light-emitting materials used in early devices were mainly organic small-molecule fluorescent materials. The spin-statistics quantum theory shows that the theoretical internal quantum efficiency of fluorescent materials is only 25%. In 1998, Professor Forrest of the Princeton University and Professor Thompson of the University of Southern California discovered the phosphorescent electroluminescence of metal-organic complex molecular materials at room temperature. The strong spin-orbit coupling of heavy metal atoms can be adopted to effectively promote the intersystem crossing (ISC) of electrons from singlet to triplet so that OLED devices can make full use of the singlet and triplet excitons generated by electrical excitation to make the theoretical internal quantum efficiency of light-emitting material reach 100% (Nature, 1998, 395, 151). After research, the photophysics and device performance of organic iridium and platinum complexes are more outstanding (Dalton Trans., 2009, 167; Chem. Soc. Rev., 2010, 39, 638; Chem. Soc. Rev., 2013, 42, 6128; J. Mater. Chem. C, 2015, 3, 913).

The cyclo-platinum (II) complex phosphorescent materials under the early study are mostly metal-organic molecules containing bidentate ligands and tridentate ligands. Due to the low rigidity of platinum complexes coordinated by bidentate ligands, the ligands are easily twisted and vibrated, resulting in low phosphorescence quantum efficiency (Inorg. Chem., 2002, 41, 3055). The cyclo-platinum (II) complexes containing tridentate ligands have increased rigidity and improved quantum efficiency, but their containing ligands other than tridentate ligands (for example, Cl, alkyne anions, carbene, etc.) makes their poor chemical stability. In comparison, tetradentate ligands can better solve the problems brought by bidentate ligands and tridentate ligands. 1. Tetradentate ligands are easily coordinated with platinum (II) to form cyclo-metal complexes with a planar quadrilateral configuration in simple synthesis without generating facial and meridional isomers that are easily obtained by iridium complexes, so the purity is high. 2. The tetradentate cyclo-platinum (II) complex has strong rigidity and high phosphorescence quantum efficiency. 3. The tetradentate cyclo-platinum (II) complex has higher chemical and thermal stability, which is beneficial to improve the stability and life of OLED devices. 4. By modifying and adjusting ligand structure, the highest occupied molecular orbital (HOMO), lowest unoccupied molecular orbital (LUMO) and triplet energy levels of the complex molecules can be controlled, thereby regulating the photophysical properties of the complex molecules.

In recent years, the tetradentate cyclo-platinum (II) complex has gotten widespread concern and good results. However, the roll-off of efficiency is one of the most serious problems of platinum(II) complexes. Generally, the platinum(II) complexes have a planar geometric structure and easily form an excimer. Therefore, only within a narrow range of doping concentration can the device with high color purity (about 1%-5% by weight) be effectively obtained. When the doping concentration is high, it is easy to form excimer emission, thereby influencing color purity and device stability, and the performance of material and device being difficultly optimized will be further increased by the narrow doping concentration range, which limits the industrial application of this type of material.

In order to solve this problem, researchers have made some efforts. In 2010, Che added tert-butyl to a red platinum (II) complex (Chem. Asian. J., 2014, 9, 2984), but π-π interactions being accumulated tightly between molecules could still be observed in the X-ray diffraction crystal structure. In 2010, Huo reported a class of platinum(II) complexes containing non-planar phenyl rings, however, excimer emission appeared at a concentration greater than 4% by weight, and severe triplet-triplet annihilation was shown in the device (Inorg. Chem., 2010, 49, 5107). In 2013, by adding a bicyclic group with large steric hindrance into the [O\hat{ }N\hat{ }C\hat{ }N] ligand, Che obtained a pure green platinum (II) complex (Chem. Commun., 2013, 49, 1497), the device efficiency of which at a doping concentration of 13% by weight was up to 66.7 cd/A, but its self-quenching constant was still relatively high (about 8.82×107 dm³mol⁻¹s⁻¹). In 2014, Che introduced a bicyclic group with large steric hindrance into the red platinum (II) complex by the same method (Chem. Eur. J., 2010, 16, 233; CN105273712B), which could effectively reduce its self-quenching constant, but the maximum doping concentration in the study was only 7%. In the same year, Che added tert-butyl groups at different positions of the [O\hat{ }N\hat{ }C\hat{ }N] ligand, with ability to effectively reduce its self-quenching constant (as low as 8.5×106 dm³mol⁻¹s⁻¹) by increasing the number of tert-butyl groups, however, as the number of tert-butyl groups increased, the emission spectrum was red-shifted, which influenced its color purity. The platinum(II) complex had maximum current efficiency of 100.5 cd/A, when doping concentration was 10% by weight in the device, but it emitted yellow-green light. When the doping concentration was further increased to 16% by weight, the device efficiency was reduced, and the color purity further deteriorated (Chem. Sci., 2014, 5, 4819). Therefore, obtaining high-efficiency and maintaining ideal color purity of Pt-based materials in a wide range of doping concentration is an urgent problem to be solved in the industry and academia.

### SUMMARY OF THE INVENTION

For the defects in the fields as mentioned above, the present invention describes a platinum (II) complex system with optimized structure, which has a simple synthesis process, a stable chemical structure, high anti-aggregation performance, and high emission quantum efficiency, and of which a high-efficient OLED with emitting pure green light can be made.

As platinum(II) complexes usually have a square planar geometric structure, the centers of platinum atoms tend to converge together, especially at high doping concentrations, the platinum(II) complexes are prone to form self-aggregation, thereby forming excimer emission and influencing emission spectrum, color purity, and device efficiency. In order to overcome this shortcoming, the present invention provides a platinum (II) tetradentate ONCN complex light-emitting material having the chemical structure of Formula I, the emission spectrum that only slightly changes or even remains unchanged at high doping concentration, and the high emission quantum efficiency, and which is more suitable for industrial preparation systems.

The present invention further provides a preparation method of the light-emitting material and application thereof in organic light-emitting diodes (OLED).

A platinum (II) tetradentate ONCN complex light-emitting material having the chemical structure of Formula I,

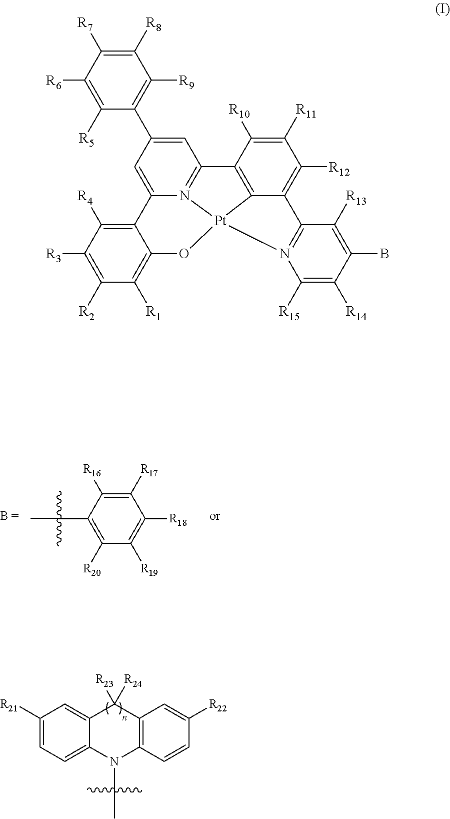

wherein R₁-R₁₅ are independently a hydrogen atom, a halogen, a hydroxyl group, an unsubstituted alkyl group, a halogenated alkyl group, a deuterated alkyl group, a cycloalkyl group, an unsubstituted aryl group, a substituted aryl group, an acyl group, an alkoxyl group, an acyloxyl group, an amino group, a nitro group, an acylamino group, an aralkyl group, a cyano group, a carboxyl group, a sulfonyl group, a styryl group, an amino carboxyl group, a carbamoyl group, an aryloxy carboxyl group, a phenoxy carboxyl or epoxy carboxyl group, a carbazole group or a diphenylamine group, and R₁-R₁₅ independently form a 5-8 membered ring with adjacent groups, and are not hydrogen at the same time; B presents an anti-aggregation group, wherein R₁₆-R₂₄ are independently a hydrogen atom, a halogen, an unsubstituted alkyl group, a halogenated alkyl group, a deuterated alkyl group, a cycloalkyl group, an unsubstituted aryl group, a substituted aryl group, a cyano group, a carbazole group, or a diphenylamine group, and n is 0 or 1 (when n is 0, B is a substituted carbazolyl group; when n is 1, B is a substituted acridinyl group).

The halogen or halogenation used in the present invention includes fluorine, chlorine, bromine, or iodine, preferably F, Cl, or Br, more preferably F or Cl, and most preferably F.

Wherein R₁-R₁₅ are independently a hydrogen atom, a halogen, a hydroxyl group, an unsubstituted alkyl group having 1 to 6 carbon atoms, a halogenated alkyl group having 1 to 6 carbon atoms, a deuterated alkyl group having 1 to 2 carbon atoms, a five- or six-membered cycloalkyl group, an unsubstituted aryl group having 6 to 10 carbon atoms, a substituted aryl group having 6 to 10 carbon atoms, an alkoxyl group having 1 to 10 carbon atoms , an amino group, a nitro group, a cyano group, a carbazolyl group, or a diphenylamine group, and independently form a 5-8 membered ring with adjacent groups, and R₁₆-R₂₄ are independently a hydrogen atom, a halogen, an unsubstituted alkyl group having 1 to 6 carbon atoms, a halogenated alkyl group having 1 to 6 carbon atoms, a five- or six-membered cycloalkyl group, an unsubstituted aryl group having 6 to 10 carbon atoms, a substituted aryl group having 6 to 10 carbon atoms, a cyano group, a carbazole group, or a diphenylamine group, and R₂₁-R₂₄ are independently a hydrogen atom, an unsubstituted alkyl group having 1 to 6 carbon atoms, or an unsubstituted aryl group having 6 to 10 carbon atoms.

Preferably, R₁-R₄ and R₁₀-R₁₂ are independently a hydrogen atom.

Preferably, R₅, R₇, and R₉ are independently a hydrogen atom, and R₆ and R₈ are independently a hydrogen atom, an unsubstituted alkyl group having 1 to 4 carbon atoms, a halogenated alkyl group having 1 to 4 carbon atoms, or a phenyl group.

Preferably, R₁₃-R₁₅ are independently a hydrogen atom, a halogen, an unsubstituted alkyl group having 1 to 6 carbon atoms, a halogenated alkyl group having 1 to 6 carbon atoms, a deuterated alkyl group having 1 to 2 carbon atoms, a five- or six-membered cycloalkyl group, an unsubstituted aryl group having 6 to 10 carbon atoms, or a substituted aryl group having 6 to 10 carbon atoms.

Preferably, R₁₇ and R₁₉ are independently a hydrogen atom, R₁₆, R₁₈, and R₂₀ are independently a hydrogen atom, a halogen, an unsubstituted alkyl group having 1 to 4 carbon atoms, a halogenated alkyl group having 1 to 4 carbon atoms, a phenyl group, a naphthyl group, or a carbazolyl group.

More preferably, R₁₃-R₁₅ are independently a hydrogen atom, an unsubstituted alkyl group having 1 to 4 carbon atoms, a trifluoromethyl group, a deuterated methyl group, or a phenyl group.

Most preferably, R₁₆, R₁₈, and R₂₀ are independently a hydrogen atom, an unsubstituted alkyl group having 1 to 4 carbon atoms, a halogenated alkyl group having 1 to 4 carbon atoms, a phenyl group, a naphthyl group, or a carbazolyl group; R₂₁ and R₂₂ are independently a hydrogen atom, an unsubstituted alkyl group having 1 to 4 carbon atoms, and R₂₃ and R₂₄ are independently an unsubstituted alkyl group having 1 to 4 carbon atoms or a phenyl group.

Some specific non-limiting examples of the platinum (II) complexes having the Formula I are as below:

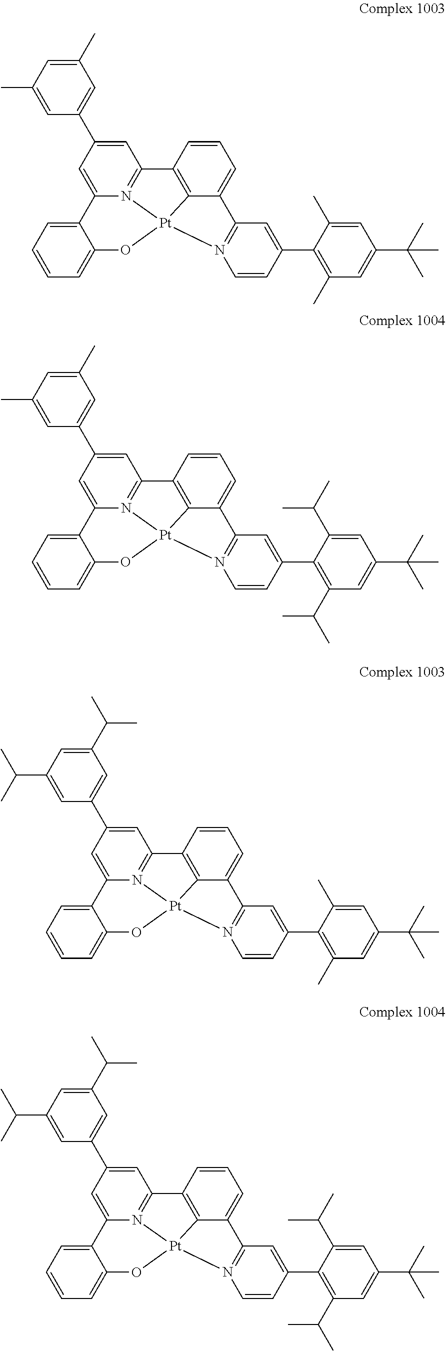

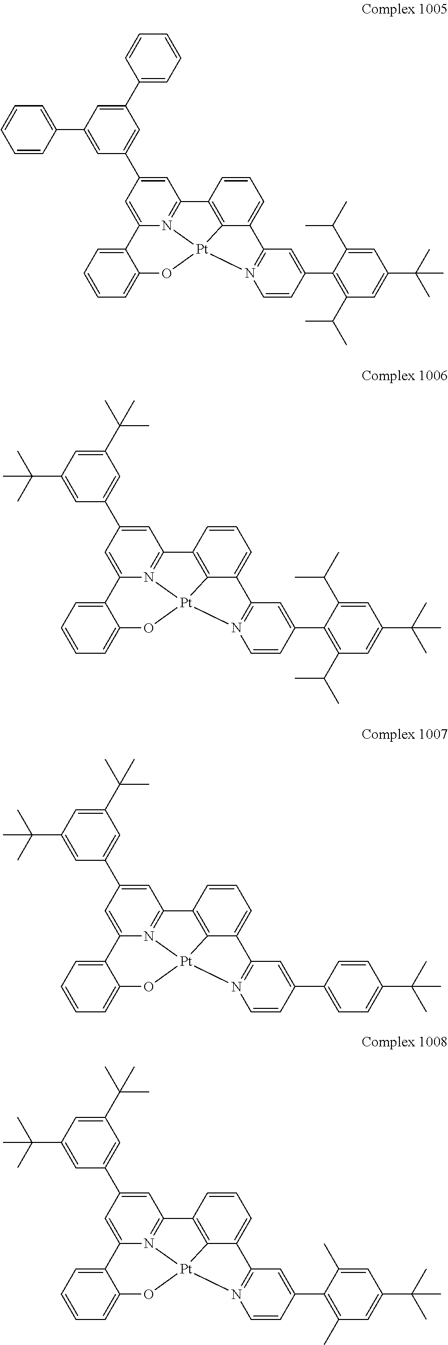

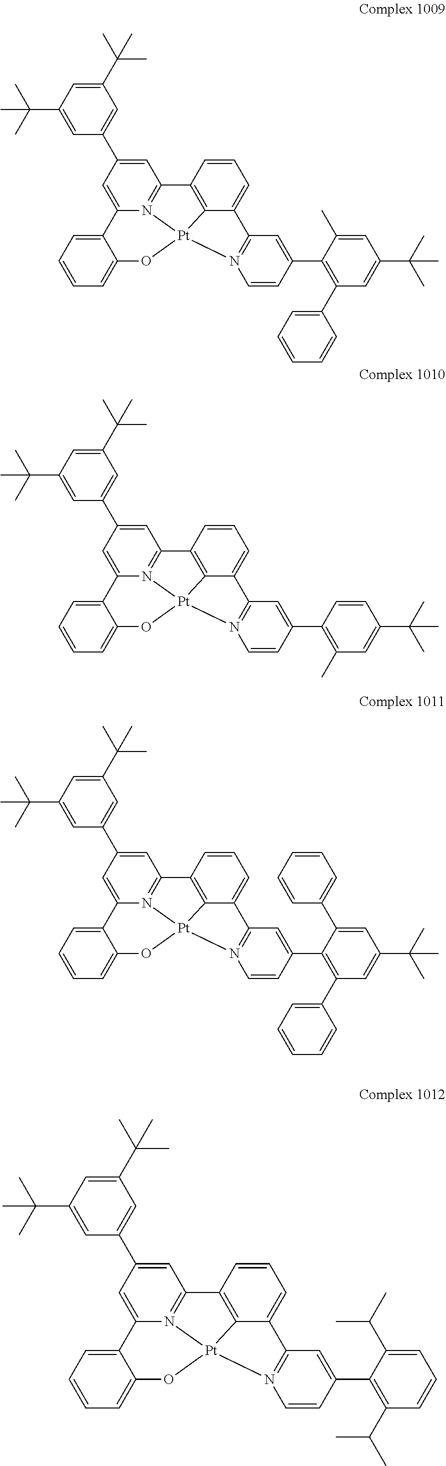

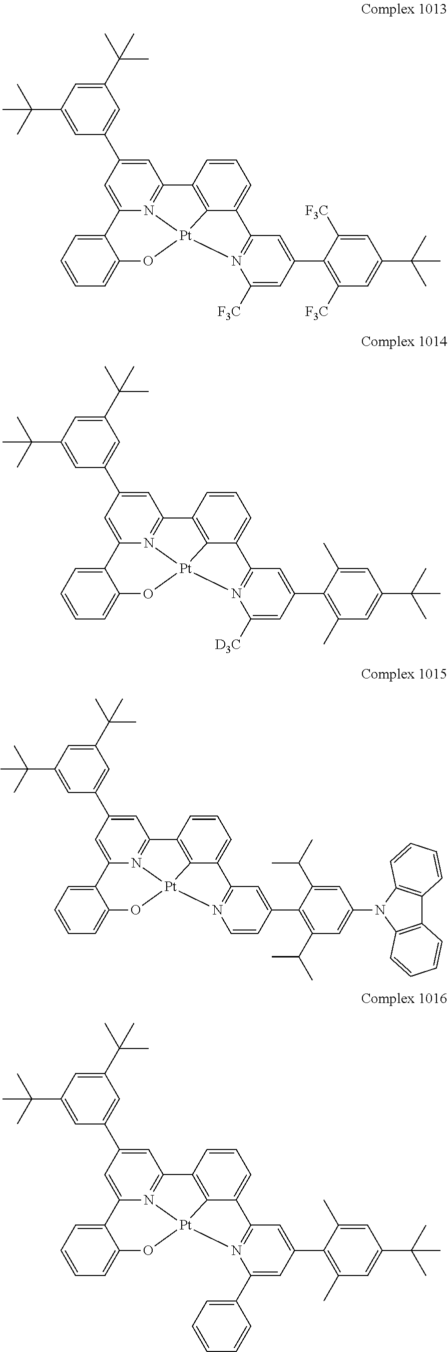

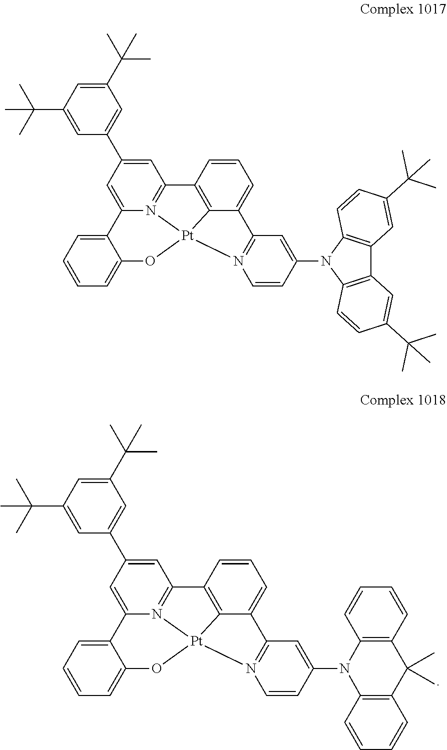

The metal-complex phosphorescent materials of the present invention can be manufactured according to the method of the following chemical equation, but are not limited to the following method:

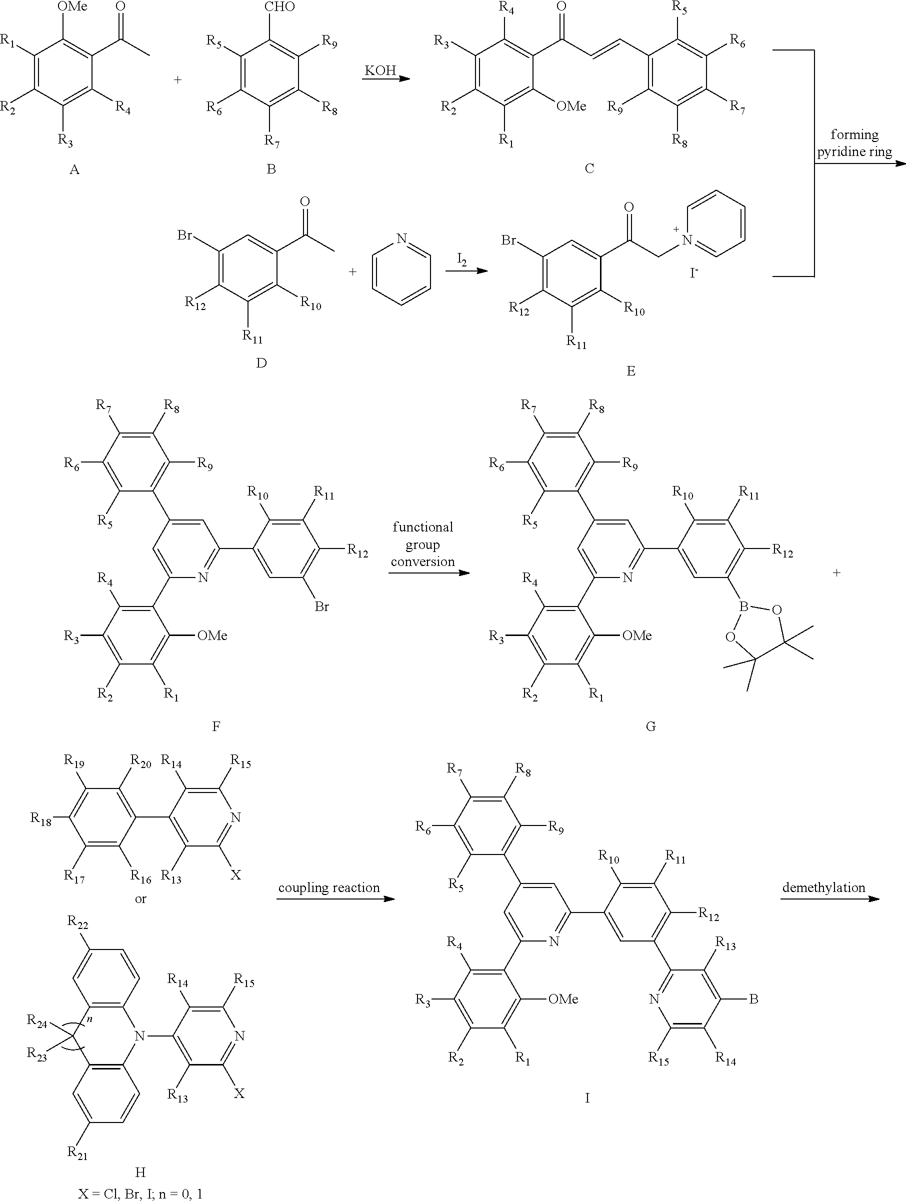

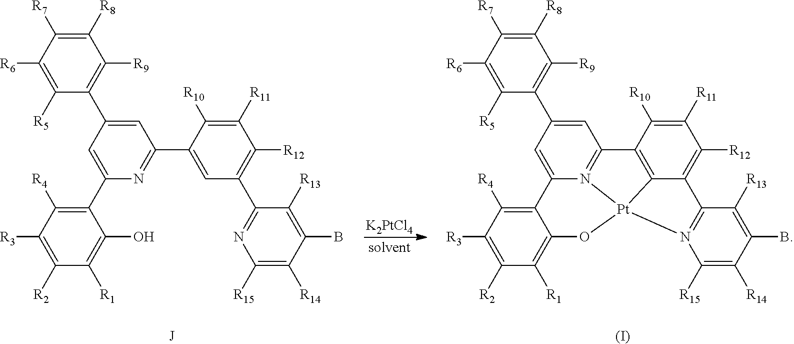

A substituted or unsubstituted O-methoxyacetophenone compound A and a substituted or unsubstituted benzaldehyde compound B are used as raw materials to obtain a substituted or unsubstituted chalcone compound C under alkaline KOH conditions. A substituted or unsubstituted M-bromoacetophenone compound D is mixed with pyridine as a solvent to obtain a pyridine salt intermediate E under iodine simple substance conditions. A pyridine intermediate F is obtained from the substituted or unsubstituted chalcone compound C and the pyridine salt intermediate E under ammonium acetate conditions. The pyridine intermediate F is converted to a borate/boric acid intermediate G by functional group conversion. The boronic ester/boronic acid intermediate G is coupled with an ortho-halogen substituted pyridine compound H (the halogen is chlorine, bromine, or iodine) by way of metal coupling (for example, carried out by using Pd(PPh₃)₄ as a catalyst and under K₂CO₃ alkali conditions) to obtain an intermediate I. A ligand J is obtained from the intermediate I by way of demethylation reaction. The ligand J reacts with a platinum compound (such as potassium tetrachloroplatinate) in a suitable solvent (such as acetic acid) at a suitable temperature (such as reflux), to obtain a platinum (II) tetradentate ONCN complex light-emitting material after purification.

A general method for synthesizing such a compound of the platinum (II) tetradentate ONCN complex light-emitting materials is provided above. The reaction materials, the reaction conditions, and the amount of usage thereof can be appropriately adjusted according to the specific reaction conditions, not limited to the above range; the reaction time and temperature according to the reaction conditions can also be adjusted, not limited to the above range.

One or two or more of the platinum (II) tetradentate ONCN complex light-emitting materials of the present invention are applied in a light-emitting layer of an organic light-emitting device. The complex having the Formula I can be adopted to form a thin film by vacuum deposition, spin coating, inkjet printing, or other known preparation methods. The present invention compounds have been used as light-emitting materials or as dopants in a light-emitting layer to manufacture different multilayer OLEDs. Specifically, the platinum(II) tetradentate ONCN complex light-emitting material of the present invention can be used as a light-emitting layer of ITO/HAT-CN/TAPC/Complex:TCTA (x wt %)/TmPyPb/LiF/Al, but not limited to the above device structure.

Cyclo-platinum (II) complex molecules with a planar quadrilateral configuration are easily coordinated and complexed with tetradentate ligands, so they can be synthesized in one step by way of metallization reaction, for their simple structures, facial and meridional isomers in iridium (III)-based complexes cannot be produced. The synthesis steps and purification process of the tetradentate ligands are simple, so high-purity ligands can be obtained, and there is no need to use extremely toxic and contaminable reagents and processes (for example, Stille coupling reaction, etc.).

The platinum(II) tetradentate ONCN complex having the structure of the Formula I shows strong emission with high solution quantum yield.

Because the platinum (II) tetradentate ONCN complex of the Formula I has a strong rigid structure, it can effectively decrease the energy consumed by molecular vibration and lessen non-radioactive decay, so high emission quantum efficiency can be obtained. High-efficiency organic light-emitting diodes (OLEDs) can be manufactured by using these complexes as light-emitting materials.

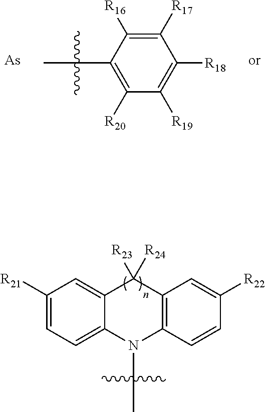

group is introduced on the terminal pyridine ring to effectively increase the anti-aggregation performance of the platinum (II) complex, to maintain ideal color purity and ideal light-emitting efficiency within a wide doping concentration range, the organic metal complex having the chemical structure of the Formula I is suitable for OLED industry to require phosphorescent materials.

In one embodiment, the OLED manufactured by using the platinum(II) tetradentate ONCN complex of the Formula I shows high efficiency greater than 100 cd/A.

In one embodiment, a device with a doping concentration of 30% does not show or hardly shows excimer emission.

In one embodiment, a device manufactured using the platinum(II) tetradentate ONCN complex of the Formula I shows green emission with CIE of (0.29±0.01, 0.65±0.01).

### BRIEF DESCRIPTION OF THE DRAWINGS

FIG. 1 is a normalized absorption spectrum and emission spectrum for 1006.

FIG. 2 is a normalized absorption spectrum and emission spectrum for 1007.

FIG. 3 is a normalized absorption spectrum and emission spectrum for 1008.

FIG. 4 is a normalized absorption spectrum and emission spectrum for 1010.

FIG. 5 is a normalized absorption spectrum and emission spectrum for 1011.

FIG. 6 is a normalized absorption spectrum and emission spectrum for 1012.

FIG. 7 is a normalized absorption spectrum and emission spectrum for 1015.

FIG. 8 is a normalized absorption spectrum and emission spectrum for 1016.

FIG. 9 is a normalized absorption spectrum and emission spectrum for 1017.

FIG. 10 is a normalized emission spectrum of an electroluminescent device for 1015.

FIG. 11 is chemical structures of Comparative Complexes 1019, 1020 and 1021

FIG. 12 is a normalized emission spectrum of an electroluminescent device for 1019.

### DETAILED DESCRIPTION OF THE INVENTION

Examples are provided for describing the implementation of the present invention as below. These examples should not be deemed as a limitation. Unless otherwise mentioned, the percentage is all by weight, and proportion of solvent mixtures is all by volume.

### EXAMPLE 1

### Synthetizing Intermediate 3106

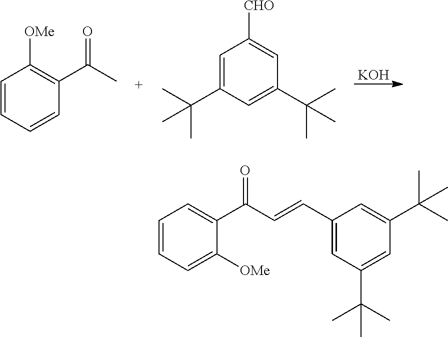

### Raw Material 4106 Raw Material 4206 Intermediate 3106

A round-bottom flask is filled with the Raw Material 4106 (0.69 mol) and the Raw Material 4206 (0.63 mol), which are stirred to dissolve by adding 1.2 L of methanol, then a potassium hydroxide aqueous solution (80 mL, 3.15 mol) is slowly dropwise added into the mixture. After finished adding, the reaction mixture is heated to 40° C. under a nitrogen atmosphere and stirred for 4 hours. After the reaction mixture is cooled to room temperature, 4 M HCl solution is added to adjust the pH of the mixture to neutralization, and the mixture is placed at −20° C. for crystallization. The solids filtered out by suction are dissolved in an organic solvent, and after the solvent is removed by evaporation, the solid product obtained is beaten with methanol at −20° C. A white solid with a yield of 85% and purity of 99.8% is obtained by suction filtration and desiccation.

### EXAMPLE 2

### Synthetizing Intermediate 3206

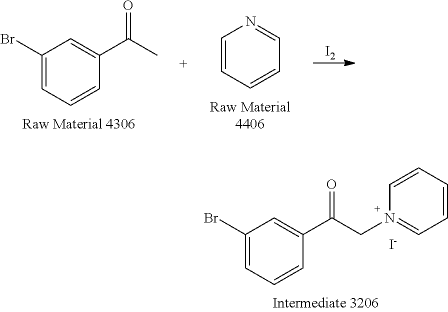

The Raw Material 4306 (0.49 mol), iodine (0.54 mol), and the Raw Material 4406 (500 mL) are put into a three-necked flask and stirred at 130° C. for 5 hours under a nitrogen atmosphere. After the completion of the reaction, the reaction fluid is cooled to room temperature with continuous stirring for 1 hour, with solids being separated out, then the precipitated solid is filtered out by suction and washed with methanol, after that the solid is further beaten with methanol. Finally a white solid with a yield of 75% is obtained by suction filtration and desiccation.

### EXAMPLE 3

### Synthetizing Intermediate 3306

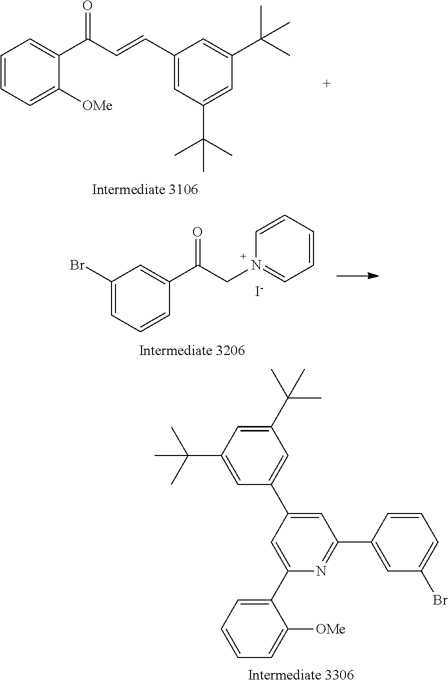

The Intermediate 3106 (0.39 mol), the Intermediate 3206 (0.39 mol), ammonium acetate (3.9 mol), and glacial acetic acid (400 mL) are put into a round-bottom flask, and stirred under reflux at 130° C. for 2 hours under a nitrogen atmosphere. During the stirring, KOH is added to adjust the pH to neutralization, and then methanol is added to separate out a solid. The solid is beaten with methanol. Finally a white solid with yield of 81% and purity of 98% is obtained by suction filtration and desiccation.

### EXAMPLE 4

### Synthetizing Intermediate 3406

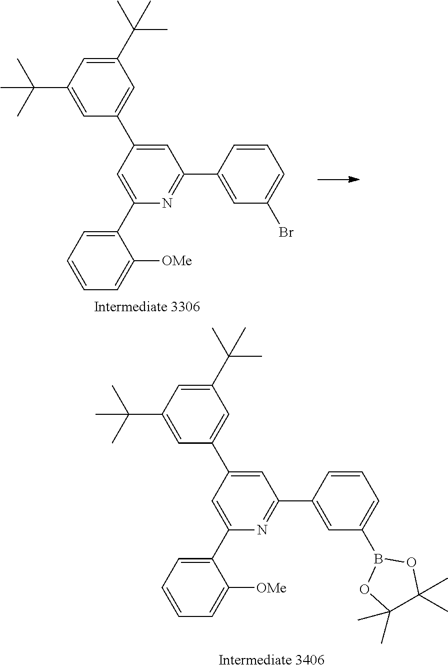 [SMILES: COc1ccccc1-c1cc(-c2cc(C(C)(C)C)cc(C(C)(C)C)c2)cc(-c2cccc(Br)c2)n1 ; COc1ccccc1-c1cc(-c2cc(C(C)(C)C)cc(C(C)(C)C)c2)cc(-c2cccc(B3OC(C)(C)C(C)(C)O3)c2)n1]

A round-bottom flask is filled with the Intermediate 3306 (0.26 mol), pinacol diboron (0.27 mol), Pd(dppf)Cl₂ (13 mmol), potassium acetate (0.78 mol), and dioxane (1 L), the temperature of which is raised to reflux under a nitrogen atmosphere, and which reacts for 5 hours. After the completion of the reaction, the reaction fluid is cooled to room temperature, filtered out by suction through a short silica gel column to remove catalyst and alkali. After an organic solvent is evaporated out under reduced pressure, the reaction fluid is stirred and beaten with methanol, and further recrystallized in an ethyl acetate-methanol solvent system, finally filtered out by suction and desiccated to obtain a white solid with a yield of 83% and purity of 99.8%.

### EXAMPLE 5

### Synthetizing Intermediate 3506

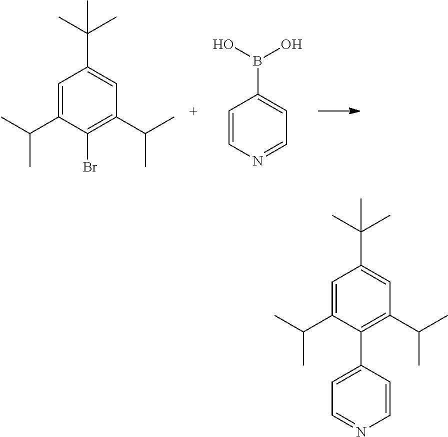 [SMILES: CC(C)c1cc(C(C)(C)C)cc(C(C)C)c1Br ; OB(O)c1ccncc1 ; CC(C)c1cc(C(C)(C)C)cc(C(C)C)c1-c1ccncc1]

Raw Material 4506 Raw Material 4606 Intermediate 3506

A round-bottom flask is filled with the Raw Material 4506 (0.1 mol), the Raw Material 4606 (1.1 mol), Pd(PPh₃)₄ (5 mmol), cesium carbonate (0.2 mol), and dioxane (200 mL), and water (40 mL), the temperature of which is raised to 90° C. under a nitrogen atmosphere, and which react for 5 hours. After the completion of the reaction, the reaction liquid is cooled to room temperature. After evaporating out an organic solvent, the reaction mixture is extracted by dichloromethane (3×100 mL), and then an organic phase is collected. Finally a colorless oily product with a yield of 89% and purity 99% is obtained by silica gel column chromatography.

### EXAMPLE 6

### Synthetizing Intermediate 3606

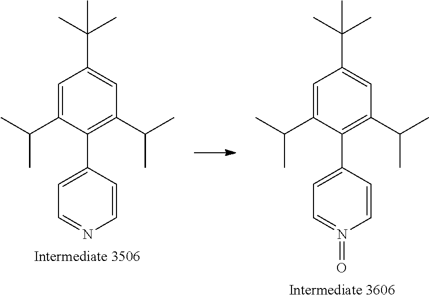 [SMILES: CC(C)c1cc(C(C)(C)C)cc(C(C)C)c1-c1ccncc1 ; CC(C)c1cc(C(C)(C)C)cc(C(C)C)c1-c1cc[n+]([O-])cc1]

The Intermediate 3506 (80 mmol) and a mixture of glacial acetic acid and 30% H₂O₂ (1:1, 100 mL) are put into a round-bottom flask, heated to 100° C., and react for 5 hours. After the completion of the reaction, moderate pure water is added to separate out white solids, which are beaten with n-hexane after suction filtration. Finally a white solid with a yield of 80% and purity of 98% is obtained by suction filtration and desiccation.

### EXAMPLE 7

### Synthetizing Intermediate 3706

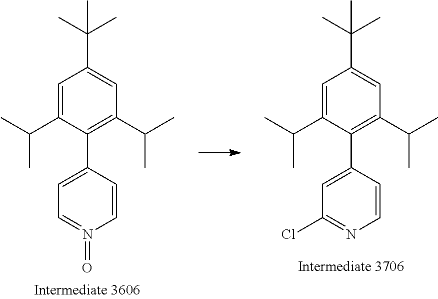 [SMILES: CC(C)c1cc(C(C)(C)C)cc(C(C)C)c1-c1cc[n+]([O-])cc1 ; CC(C)c1cc(C(C)(C)C)cc(C(C)C)c1-c1ccnc(Cl)c1]

The Intermediate 3606 (60 mmol) and phosphorus oxychloride (30 mL) are put into a round-bottom flask, heated to reflux under a nitrogen atmosphere, and react for 4 hours. After the completion of the reaction, excess phosphorus oxychloride is evaporated out. The remaining small amount of phosphorus oxychloride reaction liquid is cooled to room temperature, and slowly dropwise added into the Na₂CO₃ solution until the pH becomes neutral. Solids are separated out to obtain a crude product by suction filtration and washing, which is recrystallized with ethyl acetate-n-hexane to obtain a white solid with a yield of 80% and purity of 99%.

### EXAMPLE 8

### Synthetizing Intermediate 3806

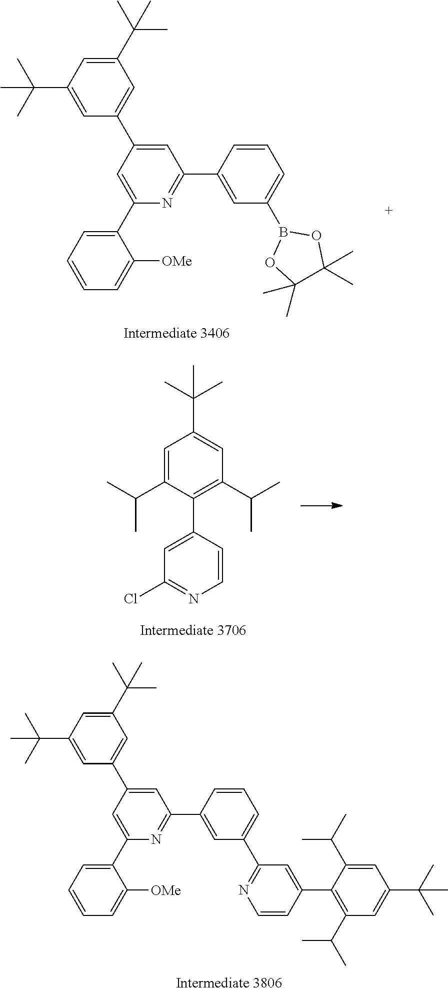

The Intermediate 3406 (10 mmol), the Intermediate 3706 (11 mmol), Pd(PPh₃)₄ (1 mmol), potassium carbonate (20 mmol), dioxane (80 mL), and water (15 mL) are put into a three-necked flask, heated to 110° C. under a nitrogen atmosphere, and react for 10 hours. After the completion of the reaction, an organic solvent is evaporated out under reduced pressure, and a remaining inorganic liquid is extracted with dichloromethane (3×50 mL) to obtain light yellow solids by purifying with silica gel column chromatography, which is further recrystallized in an ethyl acetate-methanol solvent system after being beaten with methanol, finally a light yellow solid with a yield of 83% and purity of 99.8% is obtained by suction filtration.

### EXAMPLE 9

### Synthetizing Ligand 2006

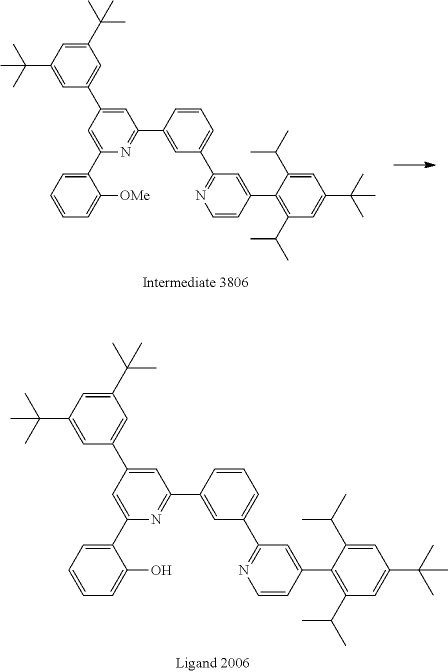

The Intermediate 3806 (8 mmol) and pyridine hydrochloride (30 g) are put into a round-bottom flask, heated to 195° C. under a nitrogen atmosphere until melt-out and stirred for 6 hours. After completion of the reaction, the mixture is cooled to room temperature, and further added with moderate pure water with being stirred evenly, after filtering out an insoluble substance by suction, then the mixture is washed with pure water, after being filtered out by suction and beaten with methanol, is further recrystallized in a dichloromethane-methanol solvent system to obtain a light yellow solid with a yield of 80% and purity with 99.8%.

### EXAMPLE 10

### Synthetizing Complex 1006

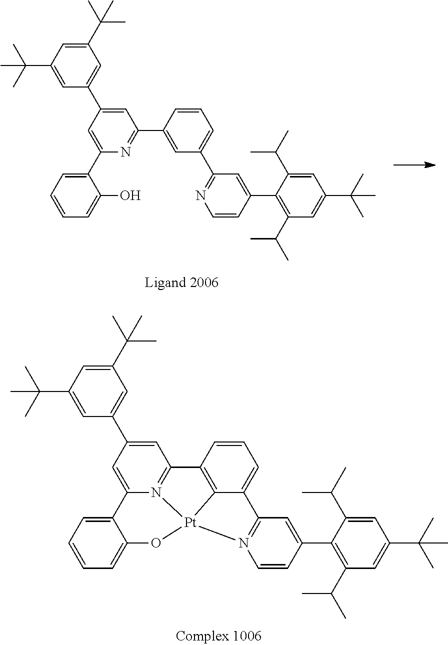

A round-bottom flask is filled with the Ligand 2006 (6 mmol), K₂PtCl₄ (7.2 mmol), glacial acetic acid (50 mL), and tetrabutylammonium bromide (0.6 mmol), and the mixture is refluxed for 16 hours under a nitrogen atmosphere. After the completion of the reaction, the reaction liquid is cooled to room temperature, added with pure water, and a yellow solid is separated out. Solids are filtered out by suction and washed with pure water until the washing liquid is neutral. The solids filtered out by suction are beaten with methanol, and then separated by silica gel column chromatography, further recrystallized in a dichloromethane-methanol solvent system. Finally, a yellow solid with a yield of 65% and purity of 99.8% is obtained by suction filtration. The absorption spectrum and emission spectrum of the Complex 1006 in dichloromethane solution at room temperature are shown in FIG. 1.

### EXAMPLE 11

### Synthetizing Intermediate 3107

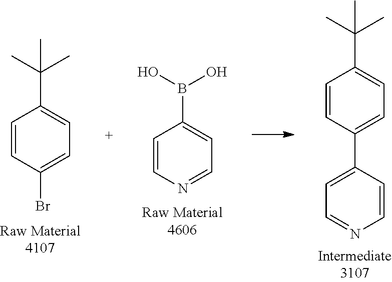 [SMILES: CC(C)(C)c1ccc(Br)cc1 ; OB(O)c1ccncc1 ; CC(C)(C)c1ccc(-c2ccncc2)cc1]

A round-bottom flask is filled with the Raw Material 4107 (33 mmol), the Raw Material 4606 (30 mmol), Pd(dppf)Cl₂ (0.9 mmol), cesium carbonate (60 mol), dioxane (50 mL), and water (10 mL), the temperature of which is raised to 100° C. in a nitrogen atmosphere, and which react for 6 hours. After the completion of the reaction, the reaction liquid is cooled to room temperature. After evaporating out an organic solvent, the reaction mixture is washed with 5% sodium bisulfite solution and extracted by dichloromethane (3×100 mL), and then an organic phase is collected. Finally a light brown solid product with a yield of 75% and purity of 98% is obtained by silica gel column chromatography.

### EXAMPLE 12

### Synthetizing Intermediate 3207

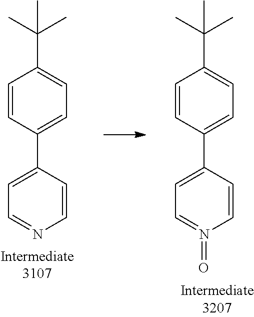 [SMILES: CC(C)(C)c1ccc(-c2ccncc2)cc1 ; CC(C)(C)c1ccc(-c2cc[n+]([O-])cc2)cc1]

The Intermediate 3207 (21 mmol) and a mixture of glacial acetic acid and 30% H₂O₂ (1:1, 20 mL) are put into a round-bottom flask, heated to 100° C., and react for 5 hours. After the completion of the reaction, moderate pure water is added to separate out white solids, which are beaten with n-hexane after suction filtration, then the product is further separated finally to obtain a white solid with a yield of 75% and purity of 98% by silica gel column chromatography.

### EXAMPLE 13

### Synthetizing Intermediate 3307

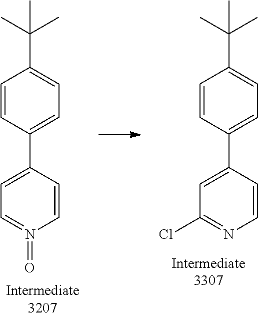 [SMILES: CC(C)(C)c1ccc(-c2cc[n+]([O-])cc2)cc1 ; CC(C)(C)c1ccc(-c2ccnc(Cl)c2)cc1]

The Intermediate 3207 (15.1 mmol) and phosphorus oxychloride (16 mL) are put into a round-bottom flask, heated to reflux under a nitrogen atmosphere, react for 4 hours. After the completion of the reaction, excess phosphorus oxychloride is evaporated out. The remaining small amount of phosphorus oxychloride reaction liquid is cooled to room temperature, and slowly dropwise added into the Na₂CO₃ solution until the pH becomes neutral. Solids are separated out to obtain a crude product by suction filtration and washing, which is separated by silica gel column chromatography to obtain a light yellow oily liquid with a yield of 61.5% and purity of 99%.

### EXAMPLE 14

### Synthetizing Intermediate 3407

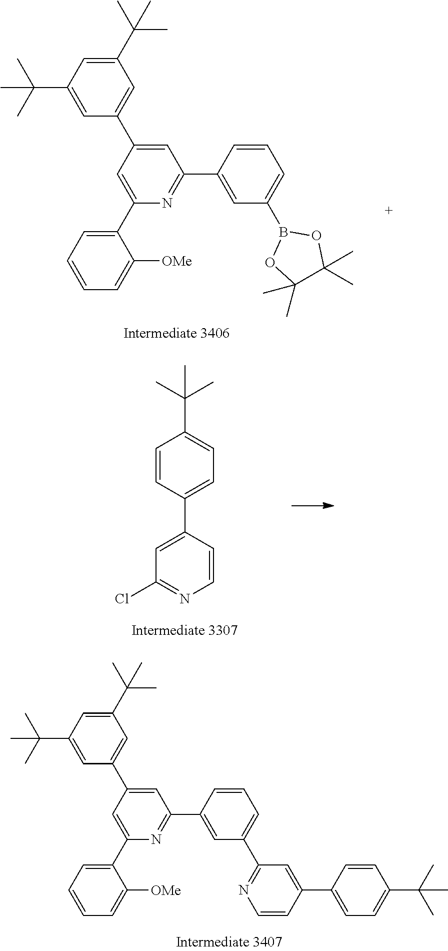

The Intermediate 3406 (7.4 mmol), the Intermediate 3308 (8.1 mmol), Pd(PPh₃)₄ (0.7 mmol), potassium carbonate (15 mmol), dioxane (40 mL), and water (8 mL) are put into a three-necked flask, heated to 110° C. under a nitrogen atmosphere, and react for 10 hours. After the completion of the reaction, an organic solvent is evaporated out under reduced pressure, and a remaining inorganic liquid is extracted with dichloromethane (3×50 mL) to obtain a white solid (n-hexane:ethyl acetate=10:1) with a yield of 92% and purity of 99% by purifying with silica gel column chromatography.

### EXAMPLE 15

### Synthetizing Ligand 2007

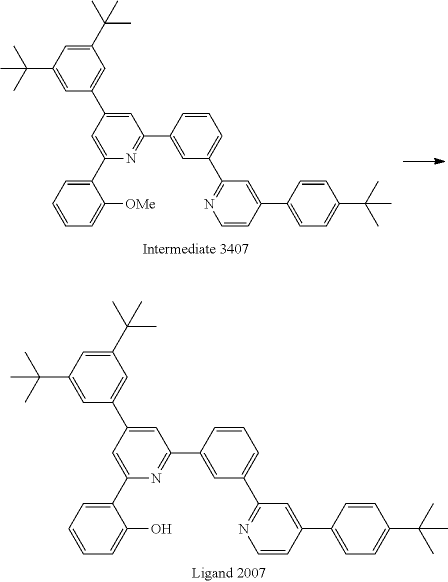

The Intermediate 3407 (5.8 mmol) and pyridine hydrochloride (40 g) are put into a round-bottom flask, heated to 195° C. under a nitrogen atmosphere until melt-out, and stirred for 10 hours, After the completion of the reaction, the mixture is cooled to room temperature, and further added with moderate pure water with being stirred evenly, after filtering out an insoluble substance by suction, then the mixture is washed with pure water, after being separated by silica gel column chromatography, is further recrystallized in an ethyl acetate-n-hexane solvent system to obtain a white solid with a yield of 87% and of purity of 99.4%.

### EXAMPLE 16

### Synthetizing Complex 1007

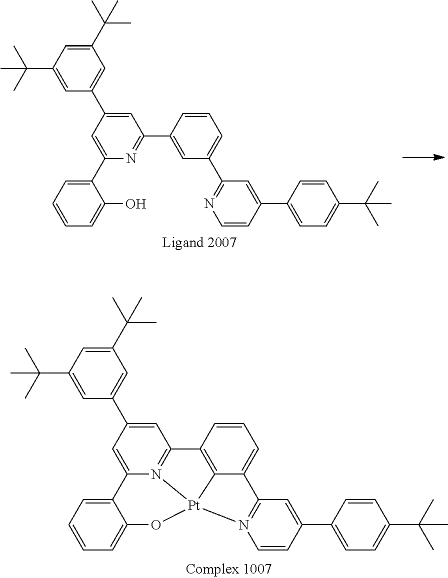

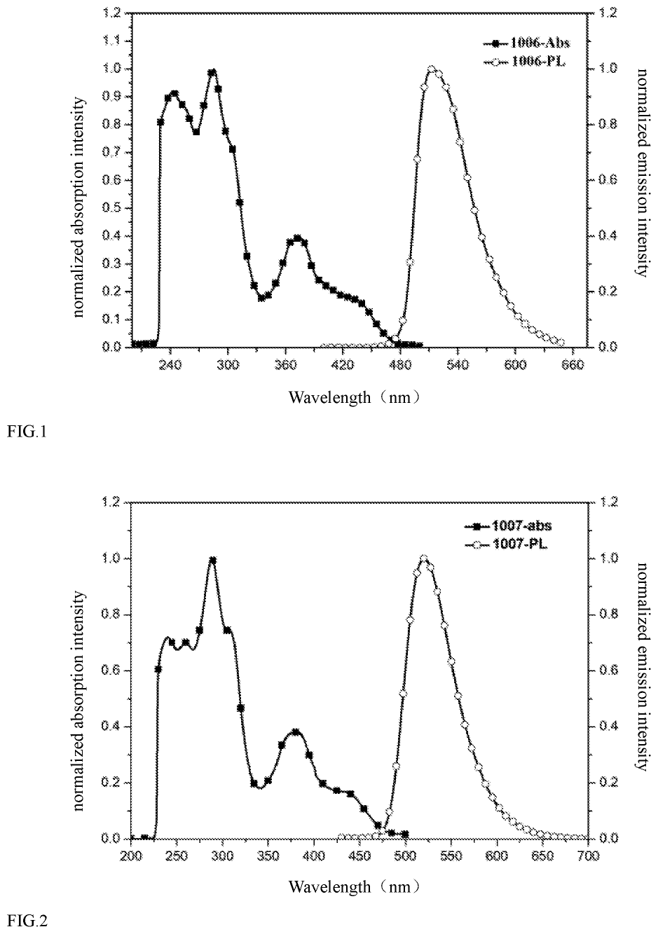

A round-bottom flask is filled with the Ligand 2007 (3.4 mmol), K₂PtCl₄ (5 mmol), glacial acetic acid (80 mL), and tetrabutylammonium bromide (0.34 mmol), and the mixture is refluxed for 16 hours under a nitrogen atmosphere. After the completion of the reaction, the reaction liquid is cooled to room temperature, added with pure water, and a yellow solid is separated out. Solids are filtered out by suction and washed with pure water until the washing liquid is neutral. The solids filtered out by suction are beaten with methanol, and then separated by silica gel column chromatography, further recrystallized in a dichloromethane-methanol solvent system. Finally, a yellow solid with a yield of 71% and purity of 99.89% is obtained by suction filtration. The absorption spectrum and emission spectrum of the Complex 1007 in dichloromethane solution at room temperature are shown in FIG. 2.

### EXAMPLE 17

### Synthetizing Intermediate 3108

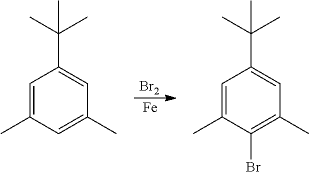

Raw Material 4108 Intermediate 3108

The Raw Material 4108 (0.24 mol) is added into a round-bottom flask and dissolved by adding 50 ml of chloroform with stirring evenly, then a catalytic amount of iron powder (0.5 g) is added at room temperature, and stirred in an ice bath for 10 minutes to cool down. Afterward, chloroform solution (50 ml) of bromine (0.26 mol) is slowly dropwise added through a constant pressure dropping-liquid funnel. After finished feeding, the ice bath is removed. When rising to room temperature and being stirred for 4 hours, the raw material is used up. The reaction liquid is poured into 200 ml of 1M sodium hydroxide solution with being stirred and washed, then separated into layers to obtain an organic phase, and an inorganic phase is extracted with dichloromethane (3×80 ml). Finally the organic solution amalgamated is washed with water to neutralization. The organic solution is dewatered by anhydrous MgSO₄, and the solvent is removed under reduced pressure to obtain a crude product. The crude product is recrystallized with ethanol to obtain a white solid with yield of 87% and purity of 99%.

### EXAMPLE 18

### Synthetizing Intermediate 3208

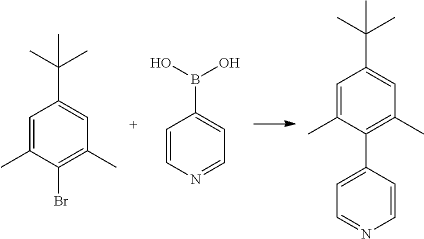

### Raw Material 4208 Raw Material 4606 Intermediate 3208

A round-bottom flask is filled with the Raw Material 4208 (20 mmol), the Raw Material 4606 (22 mmol), Pd(dppf)Cl₂ (0.8 mmol), cesium carbonate (60 mol), dioxane (50 mL), and water (10 mL), the temperature of which is raised to 100° C. in a nitrogen atmosphere, and which react for 6 hours. After the completion of the reaction, the reaction liquid is cooled to room temperature. After evaporating out an organic solvent, the reaction mixture is washed with 5% sodium bisulfite solution and extracted by dichloromethane (3×50 mL), and then an organic phase is collected, after filtering out a catalyst through short silica gel chromatography, is further recrystallized with n-hexane to obtain a white solid product with a yield of 80% and purity of 98%.

### EXAMPLE 19

### Synthetizing Intermediate 3308

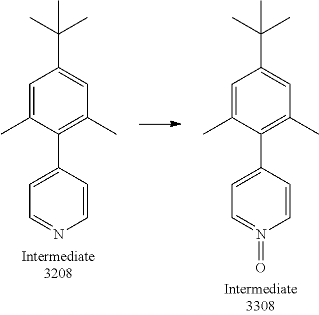

The Intermediate 3208 (15 mmol) and a mixture of glacial acetic acid and 30% H₂O₂ (1:1, 20 mL) are put into a round-bottom flask, heated to 100° C., and react for 5 hours. After the completion of the reaction, moderate pure water is added to separate out white solids, which are beaten with n-hexane after suction filtration, and which are further separated finally to obtain a white solid with a yield of 81% and purity of 98% by suction filtration.

### EXAMPLE 20

### Synthetizing Intermediate 3408

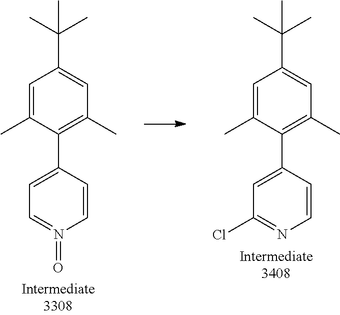

The Intermediate 3308 (12 mmol) and phosphorus oxychloride (10 mL) are put into a round-bottom flask, heated to reflux under a nitrogen atmosphere, react for 4 hours. After the completion of the reaction, excess phosphorus oxychloride is evaporated out. The remaining small amount of phosphorus oxychloride reaction liquid is cooled to room temperature, and slowly dropwise added into the Na₂CO₃ solution until the pH becomes neutral. Solids are separated out to obtain a crude product by suction filtration and washing, which is recrystallized with ethyl acetate-n-hexane to obtain a white solid with a yield of 72% and purity of 99%.

### EXAMPLE 21

### Synthetizing Intermediate 3508

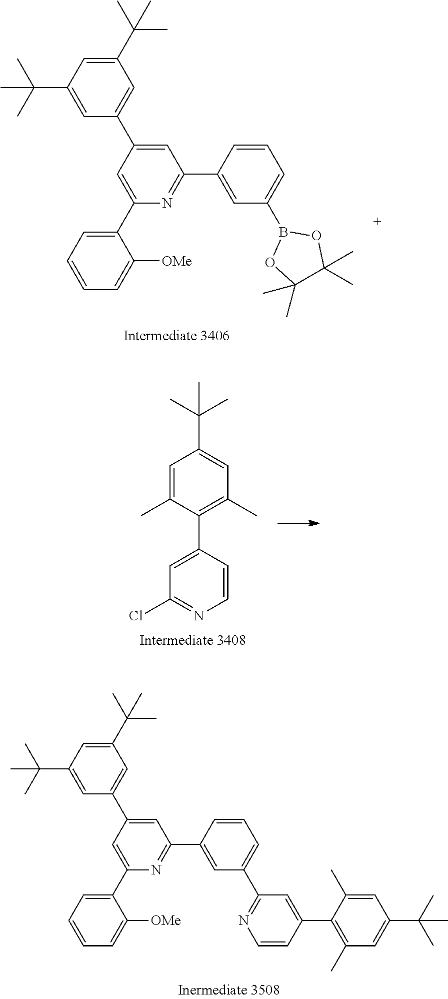

The Intermediate 3406 (7.3 mmol), the Intermediate 3408 (8 mmol), Pd₂(dba)₃ (0.4 mmol), x-phos (0.8 mmol), potassium carbonate (15 mmol), dioxane (40 mL), and water (8 mL) are put into a three-necked flask, heated to 110° C. under a nitrogen atmosphere, and react for 10 hours. After the completion of the reaction, an organic solvent is evaporated out under reduced pressure, and a remaining inorganic liquid is extracted with dichloromethane (3×50 mL). After filtering out the catalyst such as palladium by short silica gel column chromatography, the crude product is recrystallized and purified with ethyl acetate-n-hexane to obtain a white solid with a yield of 90% and purity of 99%.

### EXAMPLE 22

### Synthetizing Ligand 2008

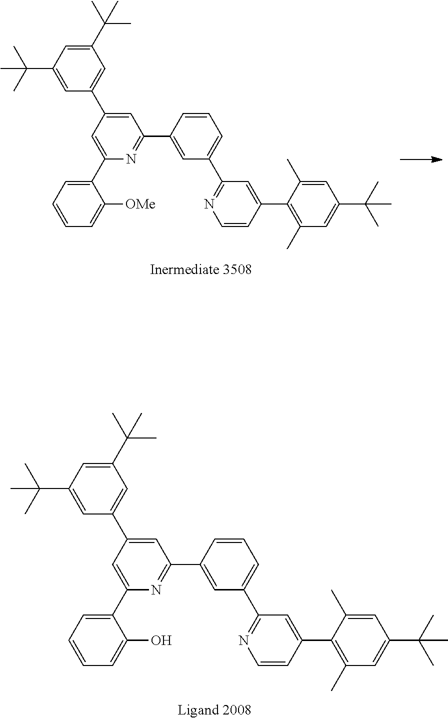

The Intermediate 3508 (6 mmol) and pyridine hydrochloride (30 g) are put into a round-bottom flask, heated to 195° C. under a nitrogen atmosphere until melt-out and stirred for 6 hours, After the completion of the reaction, the mixture is cooled to room temperature, and further added with moderate pure water with being stirred evenly, after filtering out an insoluble substance by suction, then the mixture is washed with pure water, after being separated by short silica gel column chromatography, is further recrystallized in an ethyl acetate-n-hexane solvent system to obtain a white solid with a yield of 87% and of purity of 99.4%.

### EXAMPLE 23

### Synthetizing Complex 1008

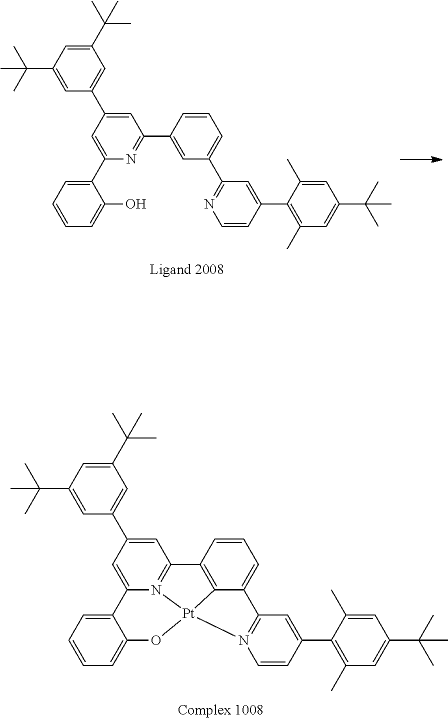

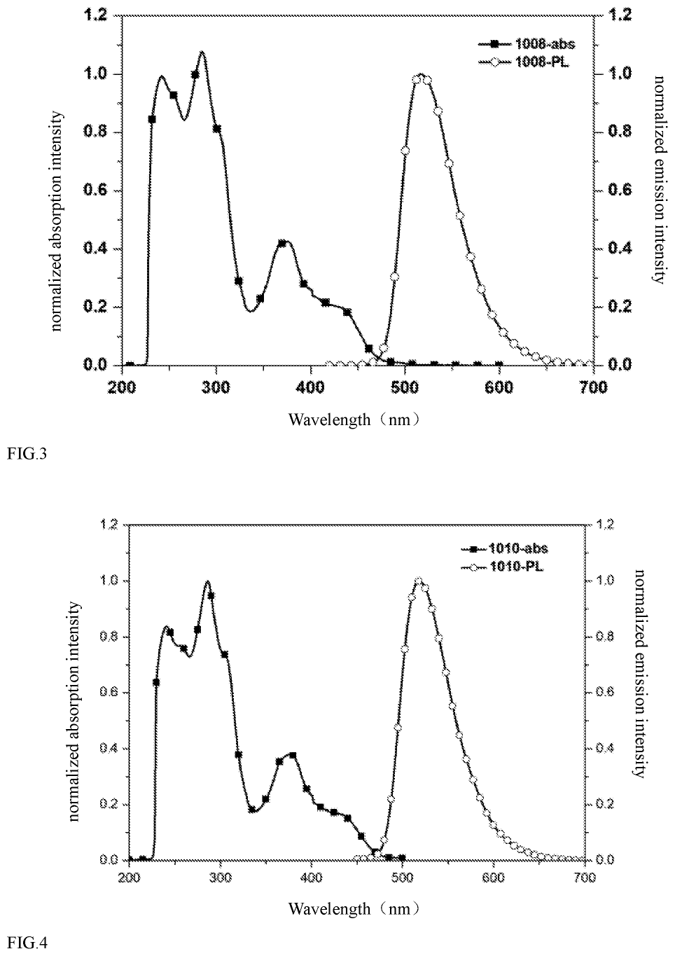

A round-bottom flask is filled with the Ligand 2008 (5 mmol), K₂PtCl₄ (6.5 mmol), glacial acetic acid (80 mL), and tetrabutylammonium bromide (0.5 mmol), and the mixture is refluxed for 16 hours under a nitrogen atmosphere. After the completion of the reaction, the reaction liquid is cooled to room temperature, added with pure water, and a yellow solid is separated out. Solids are filtered out by suction and washed with pure water until the washing liquid is neutral. The solids filtered out by suction are beaten with methanol, and then separated by silica gel column chromatography, further recrystallized in a dichloromethane-methanol solvent system. Finally, a yellow solid with a yield of 73% and purity of 99.9% is obtained by suction filtration. The absorption spectrum and emission spectrum of the Complex 1008 in dichloromethane solution at room temperature are shown in FIG. 3.

### EXAMPLE 24

### Synthetizing Intermediate 3110

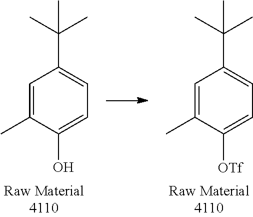 [SMILES: Cc1cc(C(C)(C)C)ccc1O ; Cc1cc(C(C)(C)C)ccc1OS(=O)(=O)C(F)(F)F]

The Raw Material 4110 (0.15 mol) is added in a round-bottom flask, and dissolved by adding 150 ml of dichloromethane with stirring evenly, then 24 mL of pyridine is added at room temperature, and stirred in an ice bath for 10 minutes to cool down. Afterward, chloroform solution (50 ml) of trifluoromethanesulfonic anhydride (0.18 mol) is slowly dropwise added. After finished feeding, the ice bath is removed. When rising to room temperature and being stirred overnight, the raw material is used up. The reaction liquid is quenched by adding 100 ml of 2M dilute hydrochloric acid solution, then separated into layers to obtain an organic phase, and an inorganic phase is extracted with dichloromethane (3×60 ml), after that the organic solution amalgamated is washed with saturated NaHCO₃ solution, finally washed with water to neutralization. The organic solution is dewatered by anhydrous MgSO₄, and the solvent is removed under reduced pressure to obtain a crude product. The crude product is separated with n-hexane as an eluent and by silica gel column chromatography to obtain a colorless transparent liquid with a yield of 57% and purity of 98%.

### EXAMPLE 25

### Synthetizing Intermediate 3210

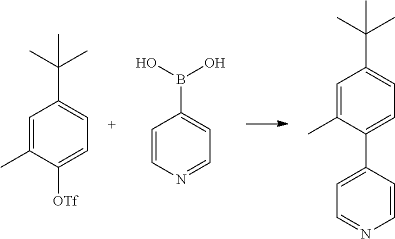 [SMILES: Cc1cc(C(C)(C)C)ccc1OS(=O)(=O)C(F)(F)F ; OB(O)c1ccncc1 ; Cc1cc(C(C)(C)C)ccc1-c1ccncc1]

Intermediate 3110 Raw Material 4606 Intermediate 3210

A round-bottom flask is filled with the Intermediate 3110 (50 mmol), the Raw Material 4606 (75 mmol), Pd(dppf)Cl₂ (1.5 mmol), cesium carbonate (0.1 mol), dioxane (150 mL) and water (30 mL), the temperature of which is raised to 100° C. in a nitrogen atmosphere, and which react for 10 hours. After the completion of the reaction, the reaction liquid is cooled to room temperature. After evaporating out an organic solvent, the reaction mixture is washed with 5% sodium bisulfite solution and extracted by dichloromethane (3×100 mL), and then an organic phase is collected. Finally a brown oily liquid product with a yield of 90.5% and purity of 97.5% is obtained by silica gel column chromatography.

### EXAMPLE 26

### Synthetizing Intermediate 3310

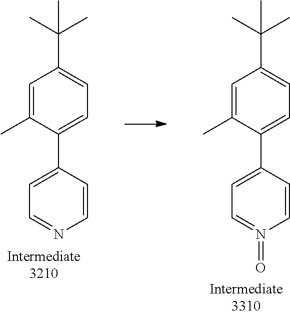 [SMILES: Cc1cc(C(C)(C)C)ccc1-c1ccncc1 ; Cc1cc(C(C)(C)C)ccc1-c1cc[n+]([O-])cc1]

A round-bottom flask is filled with the Intermediate 3210 (42 mmol) and dichloromethane (80 mL), which are stirred at room temperature, and in which 85% m-chloroperoxybenzoic acid (m-CPBA, 105 mmol) is added in batches, and stirring is continued at room temperature for 10 hours. After the completion of the reaction, a moderate 5% sodium bisulfite solution is added to wash and stir vigorously, and an inorganic phase is extracted with ethyl acetate (3×100 mL), and an organic phase is collected, then washed with 5% sodium hydroxide solution and dewatered by anhydrous sodium sulfate. The product is separated by silica gel column chromatography to obtain a white solid with a yield of 59% and purity of 99%.

### EXAMPLE 27

### Synthetizing Intermediate 3410

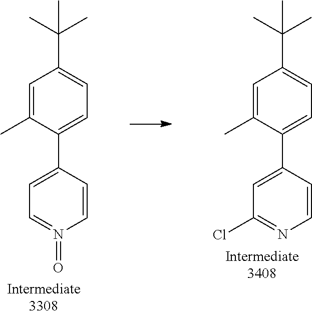 [SMILES: Cc1cc(C(C)(C)C)ccc1-c1cc[n+]([O-])cc1 ; Cc1cc(C(C)(C)C)ccc1-c1ccnc(Cl)c1]

The Intermediate 3310 (16.6 mmol) and phosphorus oxychloride (20 mL) are put into a round-bottom flask, heated to reflux under a nitrogen atmosphere, react for 4 hours. After the completion of the reaction, excess phosphorus oxychloride is evaporated out. The remaining small amount of phosphorus oxychloride reaction liquid is cooled to room temperature, and slowly dropwise added into the Na₂CO₃ solution until the pH becomes neutral. Solids are separated out to obtain a crude product by suction filtration and washing, which is separated by silica gel column chromatography to obtain a colorless oily liquid with a yield of 97% and purity of 99%.

### EXAMPLE 28

### Synthetizing Intermediate 3510

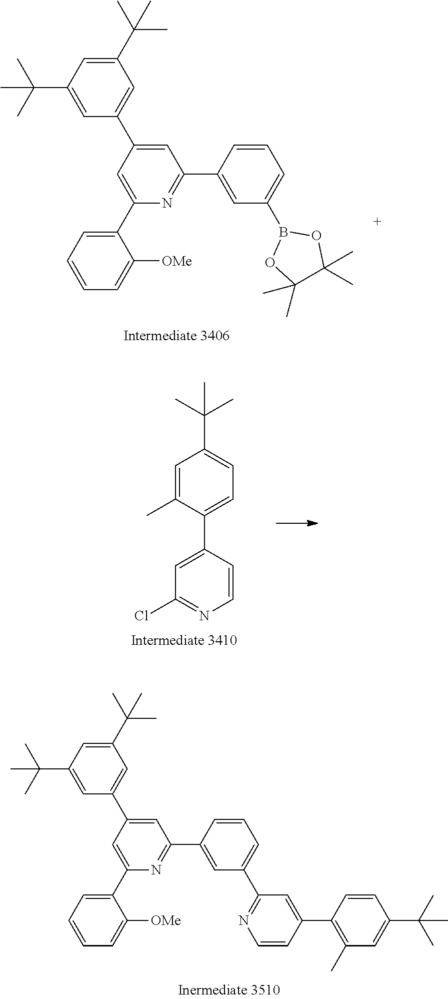

The Intermediate 3406 (8 mmol), the Intermediate 3410 (9.6 mmol), Pd(PPh₃)₄ (0.8 mmol), potassium carbonate (16 mmol), dioxane (40 mL), and water (8 mL) are put into a three-necked flask, heated to 110° C. under a nitrogen atmosphere, and react for 10 hours. After the completion of the reaction, an organic solvent is evaporated out under reduced pressure, and a remaining inorganic liquid is extracted with dichloromethane (3×50 mL) to obtain a white solid (n-hexane:ethyl acetate=10:1) with a yield of 57% and purity of 99% by purifying with silica gel column chromatography.

### EXAMPLE 29

### Synthetizing Ligand 2010

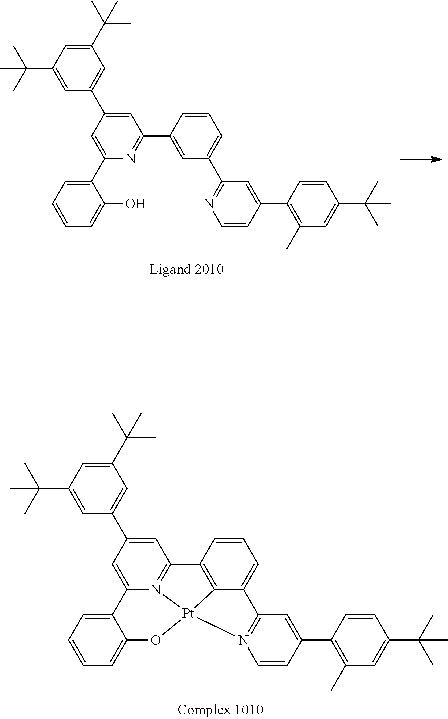

The Intermediate 3510 (5.5 mmol) and pyridine hydrochloride (40 g) are put into a round-bottom flask, heated to 195° C. under a nitrogen atmosphere until melt-out and stirred for 10 hours, After the completion of the reaction, the mixture is cooled to room temperature, and further added with moderate pure water with being stirred evenly, after filtering out an insoluble substance by suction, then the mixture is washed with pure water, after being separated by short silica gel column chromatography, is further recrystallized in an ethyl acetate-n-hexane solvent system to obtain a white solid with a yield of 99% and of purity of 99.4%.

### EXAMPLE 30

### Synthetizing Complex 1010

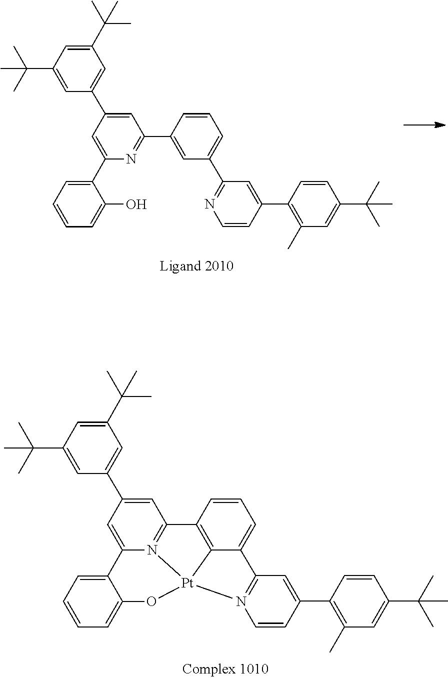

A round-bottom flask is filled with the Ligand 2010 (5.3 mmol), K₂PtCl₄ (7.4 mmol), glacial acetic acid (100 mL), and tetrabutylammonium bromide (1.6 mmol), and the mixture is refluxed for 16 hours under a nitrogen atmosphere. After the completion of the reaction, the reaction liquid is cooled to room temperature, added with pure water, and a yellow solid is separated out. Solids are filtered out by suction and washed with pure water until the washing liquid is neutral. The solids filtered out by suction are beaten with methanol, and then separated by silica gel column chromatography(n-hexane:ethyl acetate=5:1), after that beaten with methanol to obtain an orange-brown solid with a yield of 63% and purity of 98% after suction filtration and desiccation. The absorption spectrum and emission spectrum of the Complex 1010 in dichloromethane solution at room temperature are shown in FIG. 4.

### EXAMPLE 31

### Synthetizing Intermediate 3111

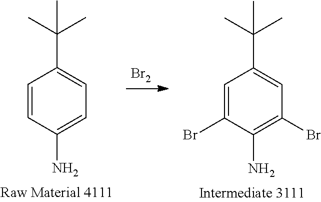

The Raw Material 4111 (0.3 mol) is added in a round-bottom flask, and dissolved by adding 200 ml of acetic acid with stirring evenly, and stirred in an ice bath for 10 minutes to cool down. Afterward, bromine (0.31 mol) is slowly dropwise added through a constant pressure low liquid funnel. After finished feeding, the ice bath is removed. When rising to room temperature and being stirred for 4 hours, the raw material is used up. The reaction liquid is poured into ice water and added with ethyl acetate, then stirred and separated into layers to obtain an organic phase, and an inorganic phase is extracted with ethyl acetate (3×100 ml). Finally the organic solution amalgamated is washed with 5% sodium bisulfite solution, further washed with 5% Na₂CO₃ to neutralization. The organic solution is dewatered by anhydrous MgSO₄, and the solvent is removed under reduced pressure to obtain a light brown oily substance with a yield of 85% and purity of 97%.

### EXAMPLE 32

### Synthetizing Intermediate 3211

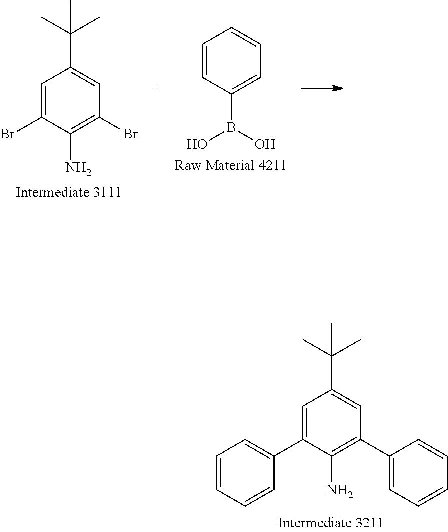 [SMILES: CC(C)(C)c1cc(Br)c(N)c(Br)c1 ; OB(O)c1ccccc1 ; CC(C)(C)c1cc(-c2ccccc2)c(N)c(-c2ccccc2)c1]

The Intermediate 3111 (50 mmol), the Raw Material 4211 (125 mmol), Pd(PPh₃)₄ (2.5 mmol), potassium carbonate (0.25 mmol), toluene (200 mL), ethanol (50 mL) and water (50 mL) are put into a three-necked flask, heated to 100° C. under a nitrogen atmosphere, and react for 10 hours with being mechanically stirred. After the completion of the reaction, water is added to forming layers to separate an organic phase, and an inorganic phase is extracted with ethyl acetate (3×150 mL). The organic phase is amalgamated and dewatered by anhydrous magnesium sulfate. After an insoluble substance is filtered out by short silica gel column chromatography and a solvent is removed under reduced pressure, it is beaten with n-hexane. Finally a beige solid with a yield of 75% and purity of 99.8% is obtained by suction filtration.

### EXAMPLE 33

### Synthetizing Intermediate 3311

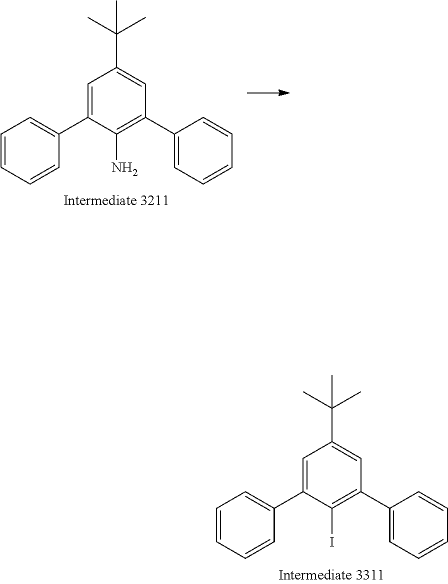 [SMILES: CC(C)(C)c1cc(-c2ccccc2)c(N)c(-c2ccccc2)c1 ; CC(C)(C)c1cc(-c2ccccc2)c(I)c(-c2ccccc2)c1]

A round-bottomed flask is filled with the Intermediate 3211 (34.4 mmol), and added with 250 ml of acetonitrile with being stirred evenly, then the temperature of the mixture is cooled to 0° C., concentrated sulfuric acid (4.8 ml) is slowly added dropwise in the admixture with stirring continued for 20 minutes. Afterward, cold NaNO₂ solution (41 mmol, 5 ml) is added dropwise at the same temperature to obtain an orange suspension with stirring continued for 30 minutes. Then the solution of KI (69 mmol) is added dropwise. After finished addition, the reaction temperature is raised to room temperature and stirring is continued for 2 hours to obtain a dark brown mixture, which is stirred and washed by adding 5% sodium bisulfite solution, and extracted with ethyl acetate. An organic phase is collected and dewatered by anhydrous magnesium sulfate. After the organic solvent is evaporated under reduced pressure, the crude product is recrystallized with methanol to obtain a white solid with a yield of 83% and purity of 99.9%.

### EXAMPLE 34

### Synthetizing Intermediate 3411

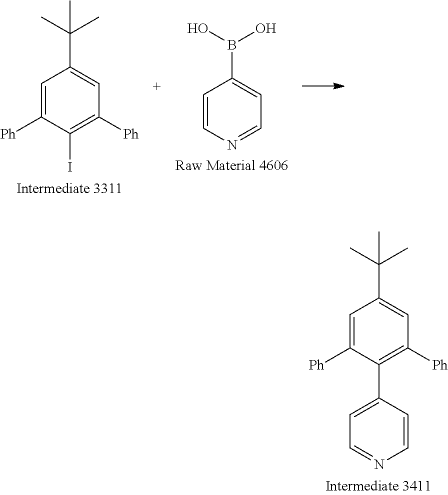 [SMILES: CC(C)(C)c1cc(-c2ccccc2)c(I)c(-c2ccccc2)c1 ; OB(O)c1ccncc1 ; CC(C)(C)c1cc(-c2ccccc2)c(-c2ccncc2)c(-c2ccccc2)c1]

A round-bottom flask is filled with the Intermediate 3311 (24.2 mol), the Raw Material 4606 (22 mmol), Pd(PPh₃)₄ (0.6 mmol), cesium carbonate (44 mmol), dioxane (200 mL), and water (40 mL)), the temperature of which is raised to 100° C. under a nitrogen atmosphere, and which react for 10 hours. After the completion of the reaction, the reaction liquid is cooled to room temperature. After evaporating out an organic solvent, the reaction mixture is extracted by dichloromethane (3×50 mL), and then an organic phase is collected and dewatered by anhydrous magnesium sulfate. Finally, a brown oily product with a yield of 84% and purity 99.8% is obtained by silica gel column chromatography.

### EXAMPLE 35

### Synthetizing Intermediate 3511

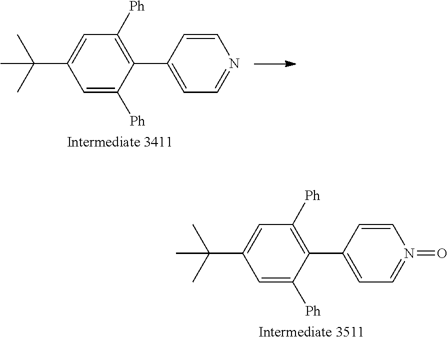 [SMILES: CC(C)(C)c1cc(-c2ccccc2)c(-c2ccncc2)c(-c2ccccc2)c1 ; CC(C)(C)c1cc(-c2ccccc2)c(-c2cc[n+]([O-])cc2)c(-c2ccccc2)c1]

The Intermediate 3411 (16.8 mmol) and a mixture of glacial acetic acid and 30% H₂O₂ (1:1, 100 mL) are put into a round-bottom flask, heated to 100° C. and react for 10 hours. After the completion of the reaction, moderate pure water is added to separate out white solids, which are beaten with n-hexane after suction filtration, and which are further separated finally to obtain a white solid with a yield of 60% and purity of 99% by suction filtration.

### EXAMPLE 36

### Synthetizing Intermediate 3611

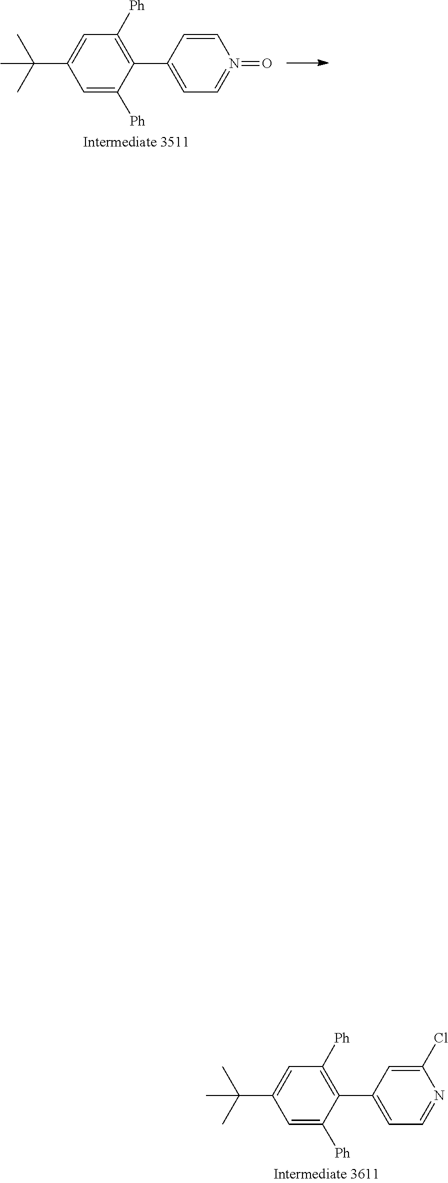 [SMILES: CC(C)(C)c1cc(-c2ccccc2)c(-c2cc[n+]([O-])cc2)c(-c2ccccc2)c1 ; CC(C)(C)c1cc(-c2ccccc2)c(-c2ccnc(Cl)c2)c(-c2ccccc2)c1]

The Intermediate 3511 (7.9 mmol) and phosphorus oxychloride (15 mL) are put into a round-bottom flask, heated to reflux under a nitrogen atmosphere, react for 4 hours. After the completion of the reaction, excess phosphorus oxychloride is evaporated out. The remaining small amount of phosphorus oxychloride reaction liquid is cooled to room temperature, and slowly dropwise added into the Na₂CO₃ solution until the pH becomes neutral. Solids are separated out to obtain a crude product by suction filtration and washing, which is recrystallized with ethyl acetate-n-hexane to obtain a white solid with a yield of 83% and purity of 99.8%, by filtering out insoluble substances and impurities by short silica gel column chromatography.

### EXAMPLE 37

### Synthetizing Intermediate 3711

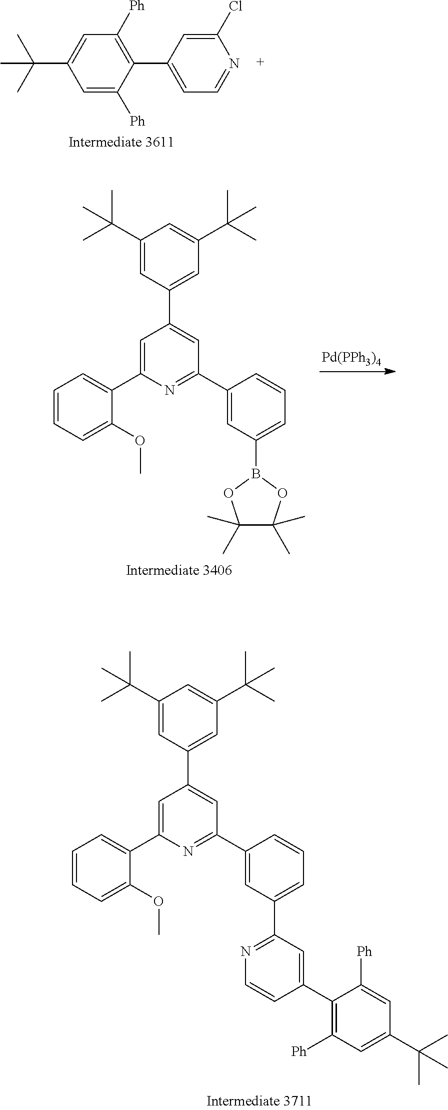 [SMILES: CC(C)(C)c1cc(-c2ccccc2)c(-c2ccnc(Cl)c2)c(-c2ccccc2)c1 ; COc1ccccc1-c1cc(-c2cc(C(C)(C)C)cc(C(C)(C)C)c2)cc(-c2cccc(B3OC(C)(C)C(C)(C)O3)c2)n1 ; COc1ccccc1-c1cc(-c2cc(C(C)(C)C)cc(C(C)(C)C)c2)cc(-c2cccc(-c3cc(-c4c(-c5ccccc5)cc(C(C)(C)C)cc4-c4ccccc4)ccn3)c2)n1 ; "Pd(PPh3)4"]

### EXAMPLE 38

### Synthetizing Ligand 2011

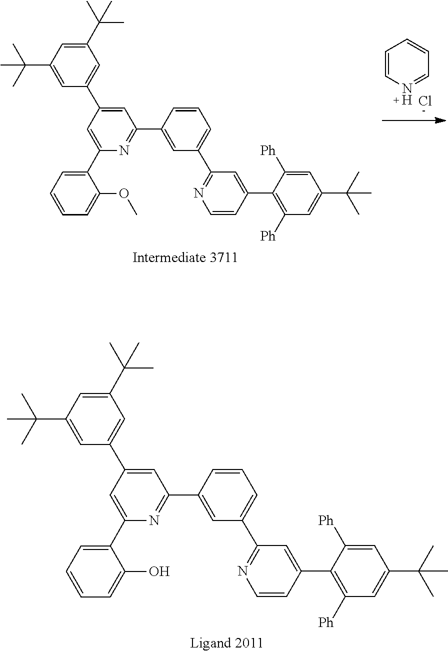

The Intermediate 3711 (2.67 mmol) and pyridine hydrochloride (15 g) are put into a round-bottom flask, heated to 195° C. under a nitrogen atmosphere until melt-out and stirred for 5 hours, After the completion of the reaction, the mixture is cooled to room temperature, and further added with moderate pure water with being stirred evenly, after filtering out an insoluble substance by suction, then the mixture is washed with pure water, after being separated by short silica gel column chromatography, is further recrystallized in an ethyl acetate-n-hexane solvent system to obtain a light yellow solid with a yield of 73% and of purity of 99.9%.

### EXAMPLE 39

### Synthetizing Complex 1011

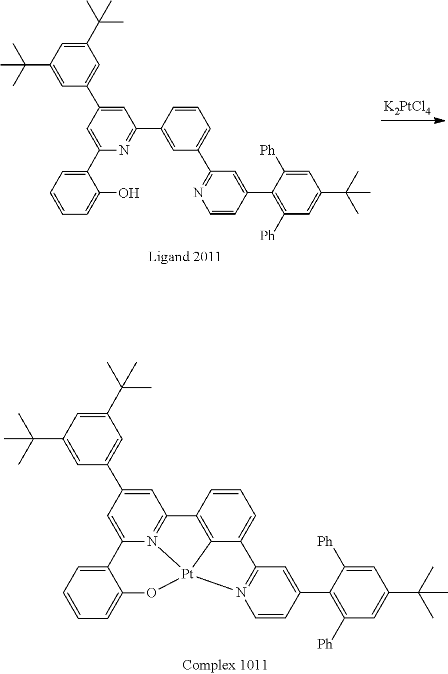

A round-bottom flask is filled with the Ligand 2011 (1.76 mmol), K₂PtCl₄ (2.1 mmol), glacial acetic acid (60 mL), and tetrabutylammonium bromide (1.8 mmol), and the mixture is refluxed for 16 hours under a nitrogen atmosphere. After the completion of the reaction, the reaction liquid is cooled to room temperature, added with pure water, and a yellow solid is separated out. Solids are filtered out by suction and washed with pure water until the washing liquid is neutral. The solids filtered out by suction are beaten with methanol, and then separated by silica gel column chromatography(n-hexane: ethyl acetate=5:1), after that beaten with methanol to obtain an orange-brown solid with a yield of 62% and purity of 99.8% after suction filtration and desiccation. The absorption spectrum and emission spectrum of the Complex 1011 in dichloromethane solution at room temperature are shown in FIG. 5.

### EXAMPLE 40

### Synthetizing Intermediate 3112

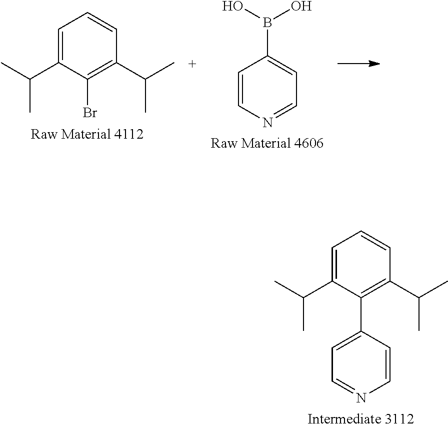 [SMILES: CC(C)c1cccc(C(C)C)c1Br ; OB(O)c1ccncc1 ; CC(C)c1cccc(C(C)C)c1-c1ccncc1]

A round-bottom flask is filled with the Raw Material 4112 (42 mmol), the Raw Material 4606 (38 mmol), Pd(dppf)Cl₂ (1.1 mmol), cesium carbonate (76 mol), dioxane (75 mL) and water (15 mL), the temperature of which is raised to 100° C. in a nitrogen atmosphere, and which react for 10 hours. After the completion of the reaction, the reaction liquid is cooled to room temperature. After evaporating out an organic solvent, the reaction mixture is washed with 5% sodium bisulfite solution and extracted by dichloromethane (3×100 mL), and then an organic phase is collected. Finally a light brown solid product with a yield of 61.7% and purity of 99% is obtained by silica gel column chromatography.

### EXAMPLE 41

### Synthetizing Intermediate 3212

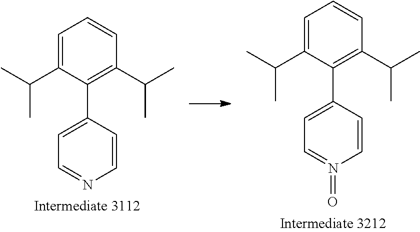 [SMILES: CC(C)c1cccc(C(C)C)c1-c1ccncc1 ; CC(C)c1cccc(C(C)C)c1-c1cc[n+]([O-])cc1]

The Intermediate 3112 (14.2 mmol) and a mixture of glacial acetic acid and 30% H₂O₂ (1:1, 20 mL) are put into a round-bottom flask, heated to 100° C. and react for 5 hours. After the completion of the reaction, moderate pure water is added to separate out white solids, which are beaten with n-hexane after suction filtration, and which are further separated to obtain a crude white solid. Finally, the product is recrystallized with ethyl acetate-n-hexane to obtain a white solid with a yield of 83.5% and purity of 99%.

### EXAMPLE 42

### Synthetizing Intermediate 3312

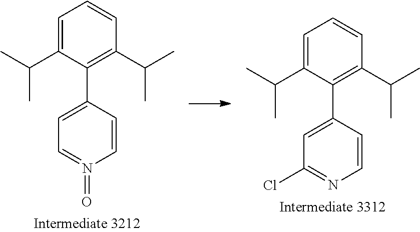 [SMILES: CC(C)c1cccc(C(C)C)c1-c1cc[n+]([O-])cc1 ; CC(C)c1cccc(C(C)C)c1-c1ccnc(Cl)c1]

The Intermediate 3212 (11.8 mmol) and phosphorus oxychloride (15 mL) are put into a round-bottom flask, heated to reflux under a nitrogen atmosphere, react for 4 hours. After the completion of the reaction, excess phosphorus oxychloride is evaporated out. The remaining small amount of phosphorus oxychloride reaction liquid is cooled to room temperature, and slowly dropwise added into the Na₂CO₃ solution until the pH becomes neutral. Solids are separated out to obtain a crude product by suction filtration and washing, which is separated by silica gel column chromatography and recrystallized with n-hexane to obtain a white solid with a yield of 88% and purity of 99.8%.

### EXAMPLE 43

### Synthetizing Intermediate 3412

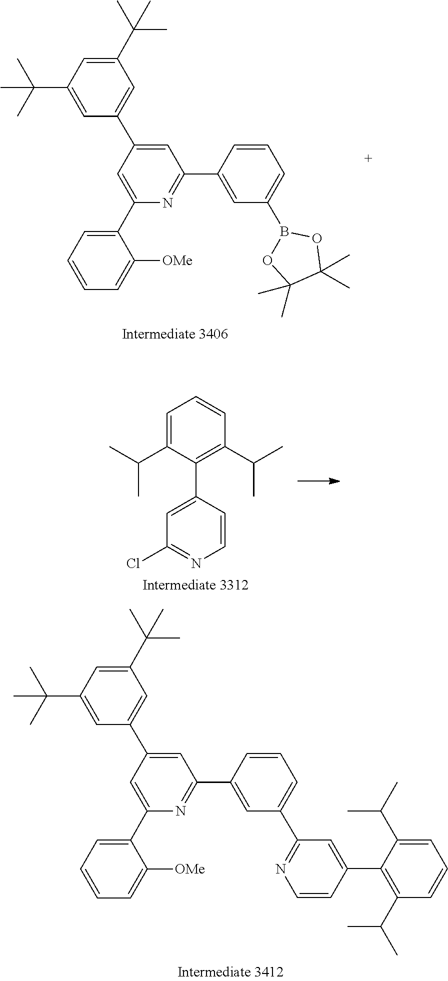

The Intermediate 3406 (8.3 mmol), the Intermediate 3312 (9.1 mmol), Pd₂(dba)₃ (0.4 mmol), x-phos (0.8 mmol), potassium carbonate (25 mmol), dioxane (60 mL), and water (8 mL) are put into a three-necked flask, heated to 110° C. under a nitrogen atmosphere, and react for 10 hours. After the completion of the reaction, an organic solvent is evaporated out under reduced pressure, and a remaining inorganic liquid is extracted with dichloromethane (3×50 mL), and a white solid (n-hexane:ethyl acetate=10:1) with a yield of 68.4% and purity of 99% is obtained by purifying with silica gel column chromatography.

### EXAMPLE 44

### Synthetizing Ligand 2012

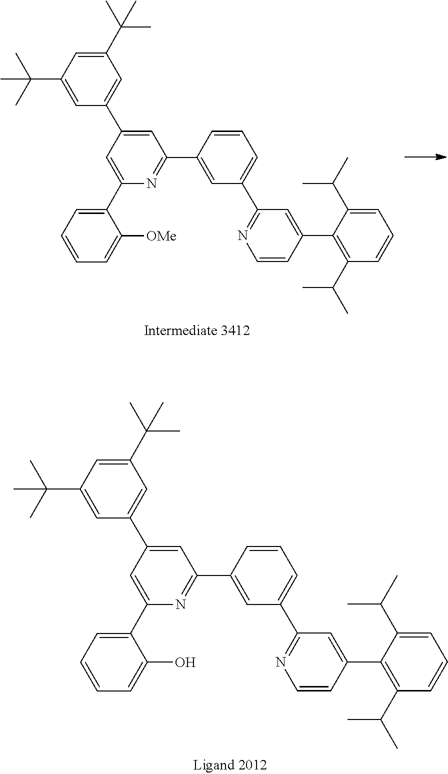 [SMILES: COc1ccccc1-c1cc(-c2cc(C(C)(C)C)cc(C(C)(C)C)c2)cc(-c2cccc(-c3cc(-c4c(C(C)C)cccc4C(C)C)ccn3)c2)n1 ; CC(C)c1cccc(C(C)C)c1-c1ccnc(-c2cccc(-c3cc(-c4cc(C(C)(C)C)cc(C(C)(C)C)c4)cc(-c4ccccc4O)n3)c2)c1]

The Intermediate 3412 (4.1 mmol) and pyridine hydrochloride (30 g) are put into a round-bottom flask, heated to 195° C. under a nitrogen atmosphere until melt-out and stirred for 5 hours, After the completion of the reaction, the mixture is cooled to room temperature, and further added with moderate pure water with being stirred evenly, after filtering out an insoluble substance by suction, then the mixture is washed with pure water, after being separated by short silica gel column chromatography, is further recrystallized in a dichloromethane-methanol solvent system to obtain a light yellow solid with a yield of 85% and of purity of 99.9%.

### EXAMPLE 45

### Synthetizing Complex 1012

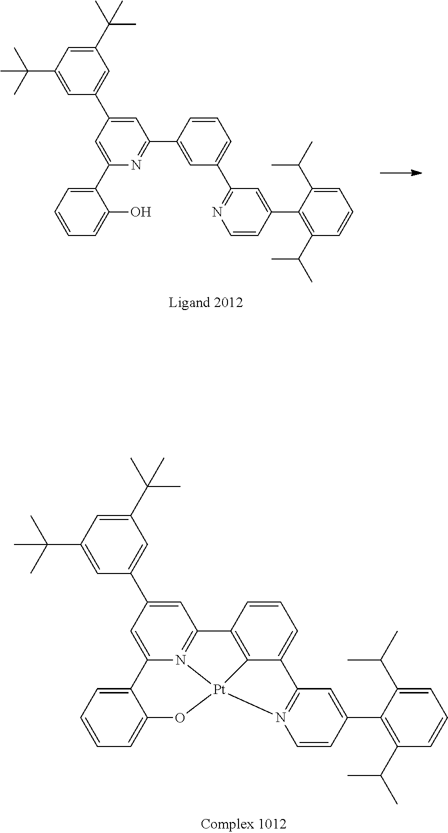

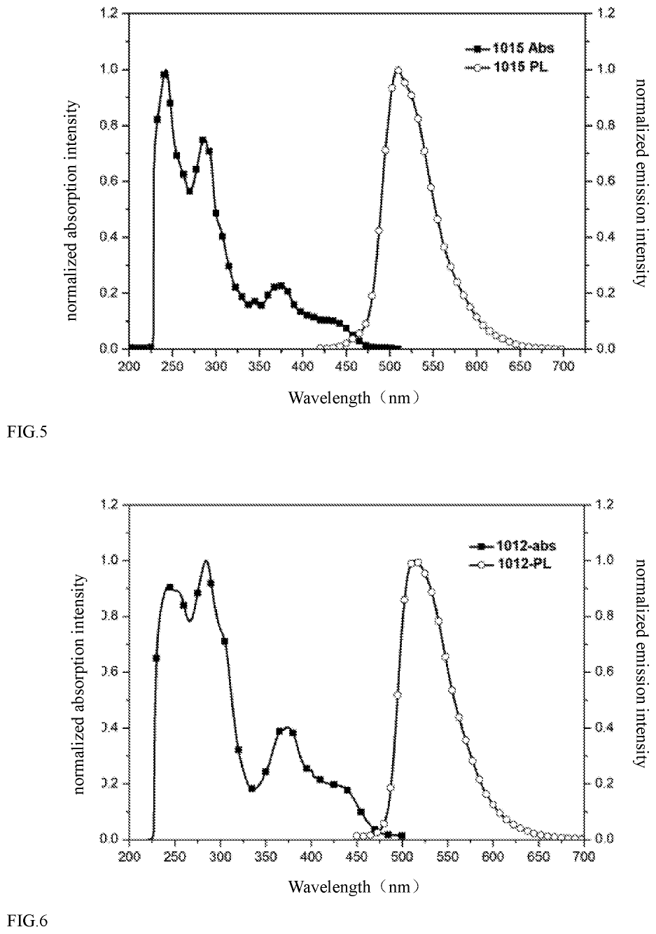

A round-bottom flask is filled with the Ligand 2012 (3.6 mmol), K₂PtCl₄ (5.7 mmol), glacial acetic acid (50 mL), and tetrabutylammonium bromide (1.1 mmol), and the mixture is refluxed for 20 hours under a nitrogen atmosphere. After the completion of the reaction, the reaction liquid is cooled to room temperature, added with pure water, and a yellow solid is separated out. Solids are filtered out by suction and washed with pure water until the washing liquid is neutral. The solids filtered out by suction are beaten with methanol, and then separated by silica gel column chromatography, after that recrystallized in a dichloromethane-methanol solvent system to obtain a yellow solid with a yield of 77.4% and purity of 99.9% after suction filtration and desiccation. The absorption spectrum and emission spectrum of the Complex 1012 in dichloromethane solution at room temperature are shown in FIG. 6.

### EXAMPLE 46

### Synthetizing Intermediate 3115

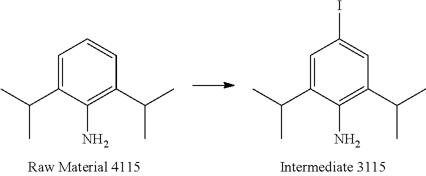

The Raw Materials 4115 (0.2 mol) and ether (200 mL) are put into a round-bottom flask, and stirred to dissolve, then iodine (0.22 mol) is added in batches, soon afterward, saturated sodium bicarbonate solution (200 mL) is added with stirring vigorously, and gas is produced. Stirring is continued for 3 hours at room temperature. After the raw material is used up by detection, sodium bisulfate (0.1 mol) is added and stirred for 1 hour to use up unreacted iodine. After lays are formed to obtain an organic phase, an inorganic phase is extracted with dichloromethane (3 □ 50 mL). After the organic phase collected is dewatered by anhydrous sodium sulfate, an organic solvent is evaporated out under reduced pressure, and the organic phase is desiccated for later use. The yield is 98% and the purity is 96%.

### EXAMPLE 47

### Synthetizing Intermediate 3215

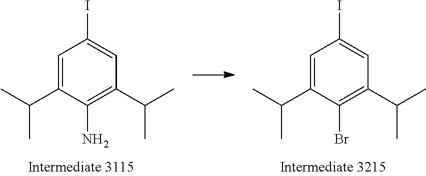

A round-bottom flask is filled with CuBr (0.165 mol), tert-butyl nitrite (0.396 mol), and acetonitrile (200 mL), which are stirred evenly, and is slowly added dropwise with acetonitrile solution (100 mL) of the Intermediate 3115 (0.165 mol), after finished addition, the temperature is raised to 70° C. and with stirring for 5 hours. After the completion of the reaction, moderate water is added to extract an organic phase with ethyl acetate (3×80 mL). The organic phase collected, after being dewatered, is pinned dry, then separated by using n-hexane as an eluent and by silica gel column chromatography to obtain a purple oily substance with a yield of 60% and purity of 97%.

### EXAMPLE 48

### Synthetizing Intermediate 3315

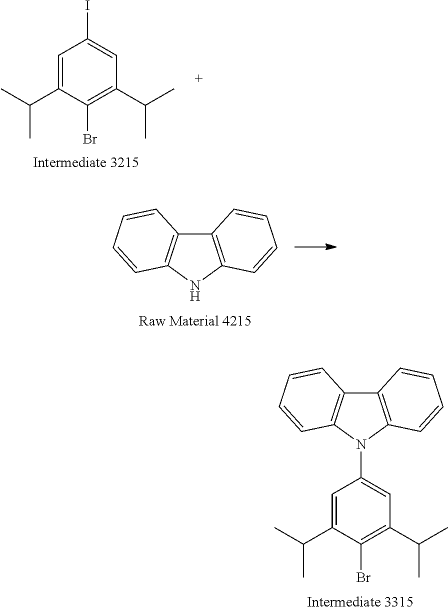 [SMILES: CC(C)c1cc(I)cc(C(C)C)c1Br ; c1ccc2c(c1)[nH]c1ccccc12 ; CC(C)c1cc(-n2c3ccccc3c3ccccc32)cc(C(C)C)c1Br]

The Intermediate 3215 (68 mmol), the Raw Material 4215 (68 mmol), o-phenanthroline (27 mmol), CuI (13.5 mmol), potassium carbonate (170 mmol), and DMSO (100 mL) are put into a three-necked flask, heated to 120° C. under a nitrogen atmosphere and react for 10 hours. After the completion of the reaction, 300 mL of water is added to separate out a gray solid, which is washed with water after suction filtration. A crude product is beaten with methanol, filtered and desiccated to obtain a white solid with a yield of 82.4% and purity of 97%.

### EXAMPLE 49

### Synthetizing Intermediate 3415

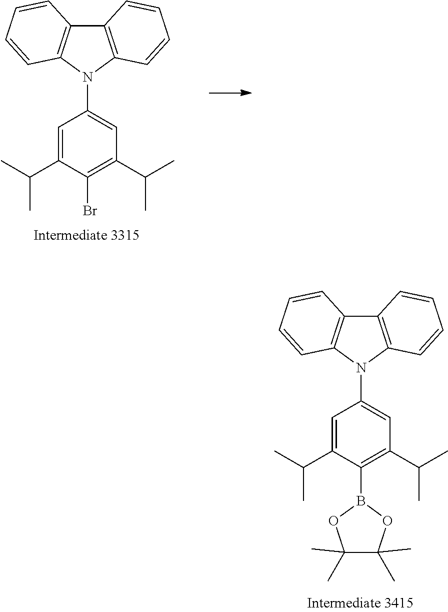 [SMILES: CC(C)c1cc(-n2c3ccccc3c3ccccc32)cc(C(C)C)c1Br ; CC(C)c1cc(-n2c3ccccc3c3ccccc32)cc(C(C)C)c1B1OC(C)(C)C(C)(C)O1]

A three-necked flask is filled with the Intermediate 3315 (49 mmol) and anhydrous THF (140 mL), which are protected by nitrogen. The reaction liquid is placed in a low temperature reactor at −78° C. and stirred for 20 minutes. Then, n-butyllithium (2M, 73 mmol) is slowly added dropwise, and after finished addition, the temperature is maintained and stirring is continued for 1 hour. After that, isopropanol pinacol borate (73 mmol) is added via a syringe, and then the temperature rises naturally to room temperature with stirring for 10 hours. After the completion of the reaction, saturated ammonium chloride solution is added to form layers to obtain an organic phase, and an inorganic phase is extracted with ethyl acetate (3×50 mL). After concentration, a white solid with a yield of 55% and purity of 98% is obtained by separating with silica gel column chromatography.

### EXAMPLE 50

### Synthetizing Intermediate 3515

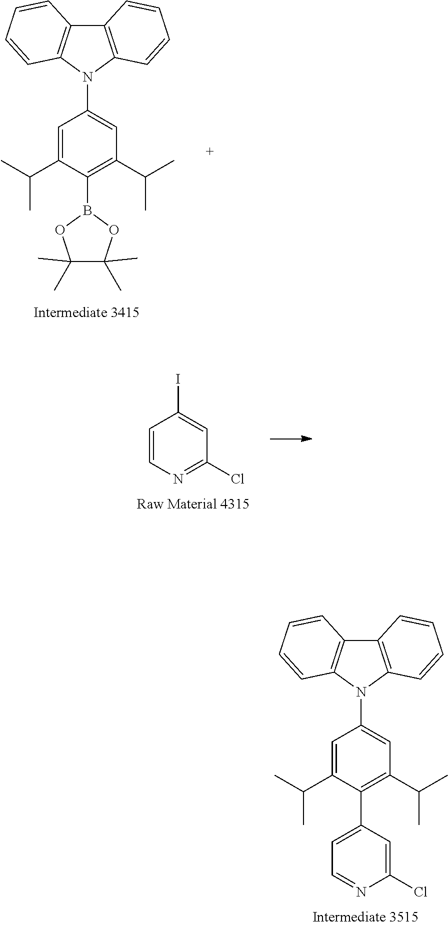 [SMILES: CC(C)c1cc(-n2c3ccccc3c3ccccc32)cc(C(C)C)c1B1OC(C)(C)C(C)(C)O1 ; Clc1cc(I)ccn1 ; CC(C)c1cc(-n2c3ccccc3c3ccccc32)cc(C(C)C)c1-c1ccnc(Cl)c1]

The Intermediate 3415 (20 mmol), the Intermediate 4315 (20 mmol), Pd (dppf)Cl₂ (1 mmol), sodium hydroxide (40 mmol), dioxane (50 mL), and water (10 mL) are put into a three-necked flask, heated to 110° C. under a nitrogen atmosphere, and react for 10 hours. After the completion of the reaction, an organic solvent is evaporated out under reduced pressure, and a remaining inorganic liquid is extracted with dichloromethane (3×50 mL), and a white solid (n-hexane:ethyl acetate=15:1) with a yield of 89% and purity of 99% is obtained by purifying with silica gel column chromatography.

### EXAMPLE 51

### Synthetizing Intermediate 3615

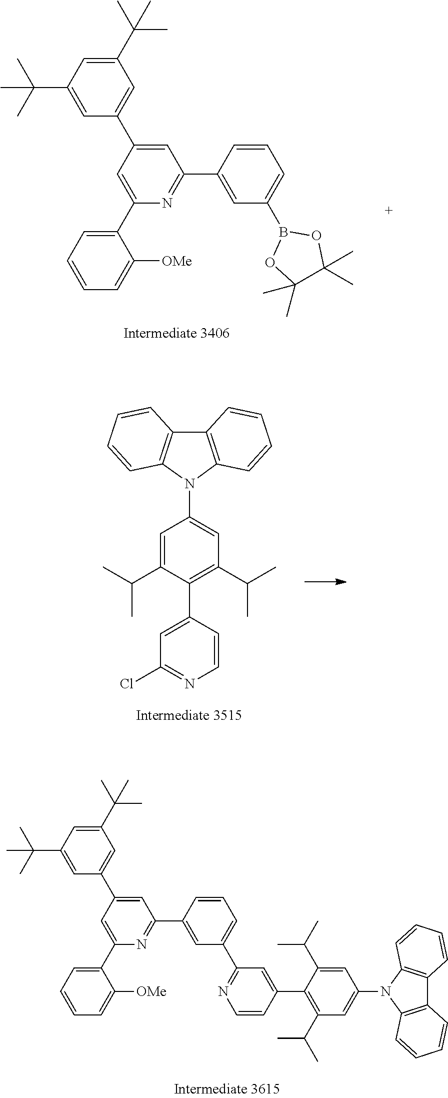

The Intermediate 3406 (15.5 mmol), the Intermediate 3515 (17 mmol), Pd₂(dba)₃ (0.8 mmol), x-phos(1.6 mmol), potassium carbonate (31 mmol), dioxane (80 mL), and water (16 mL) are put into a three-necked flask, heated to 110° C. under a nitrogen atmosphere, and react for 10 hours. After the completion of the reaction, an organic solvent is evaporated out under reduced pressure, and a remaining inorganic liquid is extracted with dichloromethane (3×50 mL), and a white solid (n-hexane:ethyl acetate=10:1) with a yield of 78.5% and purity of 99.7% is obtained by purifying with silica gel column chromatography.

### EXAMPLE 52

### Synthetizing Ligand 2015

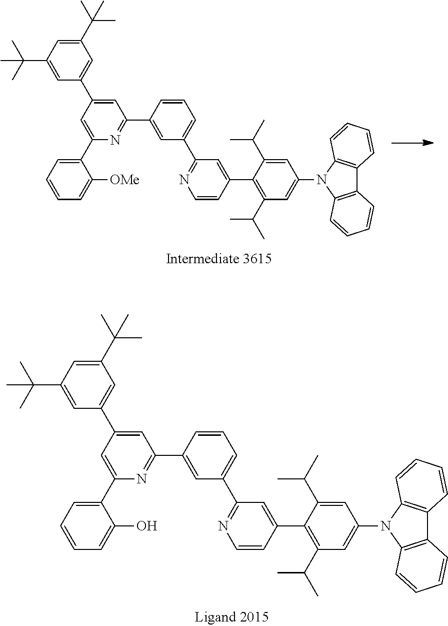 [SMILES: COc1ccccc1-c1cc(-c2cc(C(C)(C)C)cc(C(C)(C)C)c2)cc(-c2cccc(-c3cc(-c4c(C(C)C)cc(-n5c6ccccc6c6ccccc65)cc4C(C)C)ccn3)c2)n1 ; CC(C)c1cc(-n2c3ccccc3c3ccccc32)cc(C(C)C)c1-c1ccnc(-c2cccc(-c3cc(-c4cc(C(C)(C)C)cc(C(C)(C)C)c4)cc(-c4ccccc4O)n3)c2)c1]

The Intermediate 3615 (12 mmol) and pyridine hydrochloride (100 g) are put into a round-bottom flask, heated to 195° C. under a nitrogen atmosphere until melt-out and stirred for 6 hours, After the completion of the reaction, the mixture is cooled to room temperature, and further added with moderate pure water with being stirred evenly, after filtering out an insoluble substance by suction, then the mixture is washed with pure water, after being separated by short silica gel column chromatography, is further beaten with methanol to obtain a light yellow solid with a yield of 88% and of purity of 99.8%.

### EXAMPLE 53

### Synthetizing Complex 1015

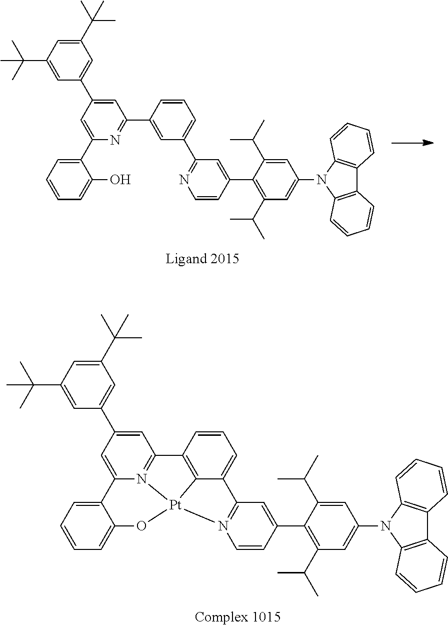

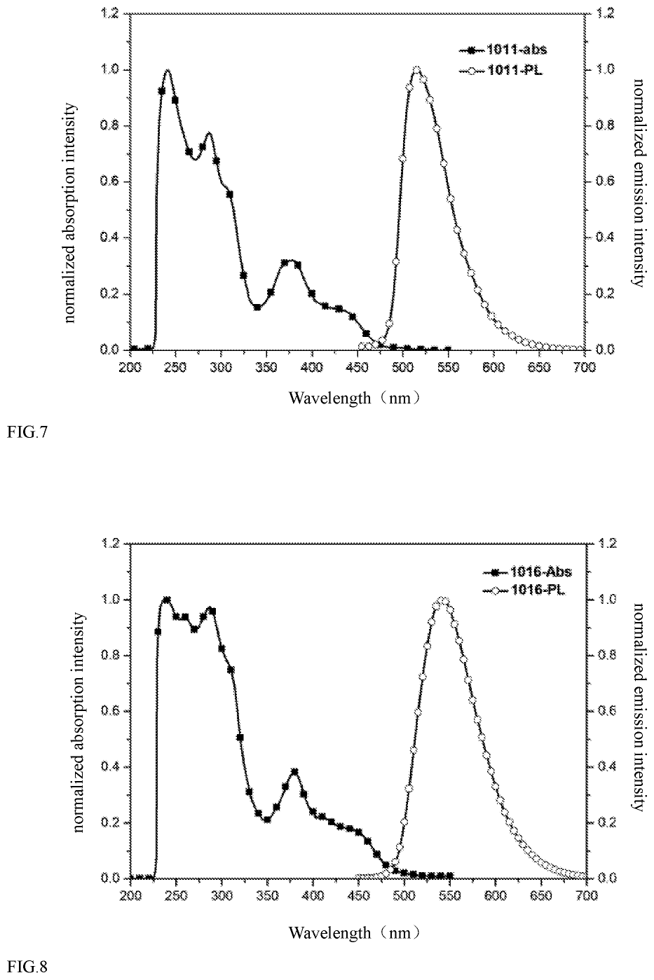

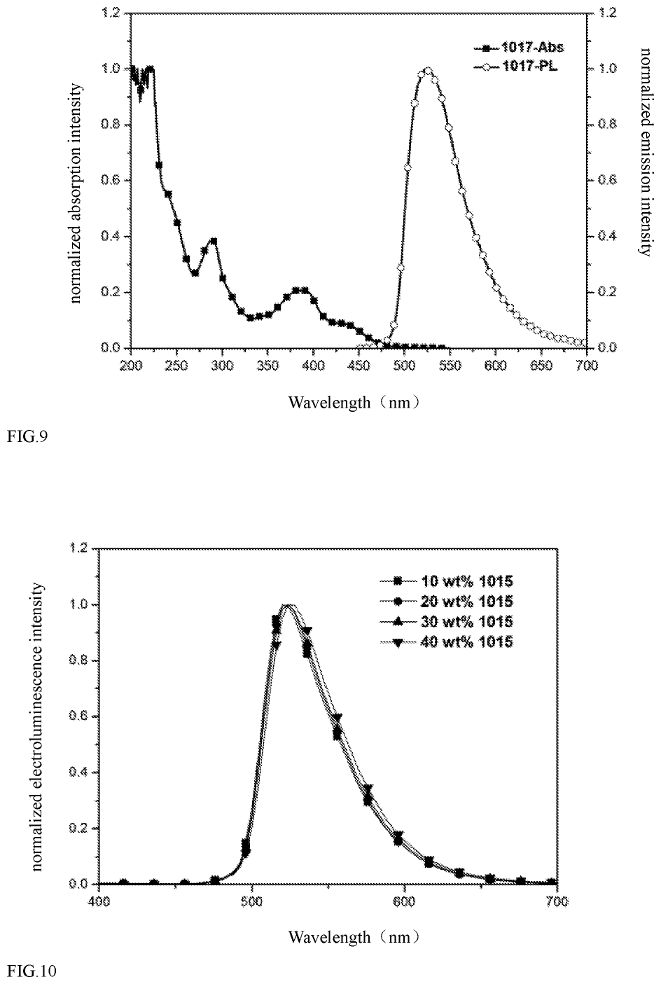

A round-bottom flask is filled with the Ligand 2015 (10 mmol), K₂PtCl₄ (12 mmol), glacial acetic acid (300 mL), and tetrabutylammonium bromide (2 mmol), and the mixture is refluxed for 20 hours under a nitrogen atmosphere. After the completion of the reaction, the reaction liquid is cooled to room temperature, added with pure water, and a yellow solid is separated out. Solids are filtered out by suction and washed with pure water until the washing liquid is neutral. The solids filtered out by suction are beaten with methanol, and then separated by silica gel column chromatography, after that recrystallized in a dichloromethane-methanol solvent system to obtain a yellow solid with a yield of 75% and purity of 99.8% after suction filtration and desiccation. The absorption spectrum and emission spectrum of the Complex 1015 in dichloromethane solution at room temperature are shown in FIG. 7.

### EXAMPLE 54

### Synthetizing Intermediate 3116

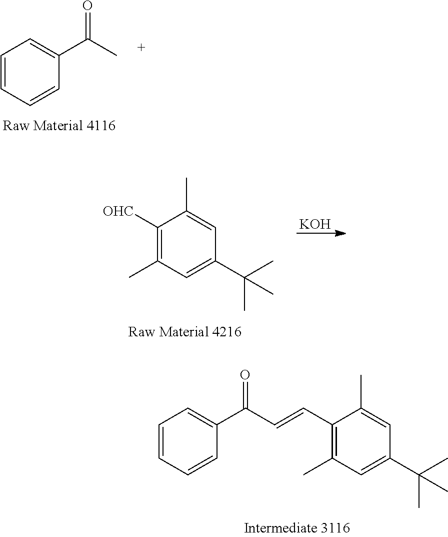

A round-bottom flask is filled with the Raw Material 4116 (0.1 mol) and the Raw Material 4216 (0.105 mol), which are stirred to dissolve by adding 1.2 L of methanol, then a potassium hydroxide aqueous solution (20 mL, 0.55 mol) is slowly dropwise added into the mixture. After finished adding, the reaction mixture is heated to 40° C. under a nitrogen atmosphere and stirred for 4 hours. After the reaction mixture is cooled to room temperature, 4 M HCl solution is added to adjust the pH of the mixture to neutralization, and the mixture is placed at −20° C. for crystallization. The solids filtered out by suction are dissolved in an organic solvent, and after an insoluble substance is filtered out and the solvent is removed, the solid product obtained is beaten with methanol at −20° C. A white solid with a yield of 78% and purity of 98% is obtained by suction filtration and desiccation.

### EXAMPLE 55

### Synthetizing Intermediate 3216

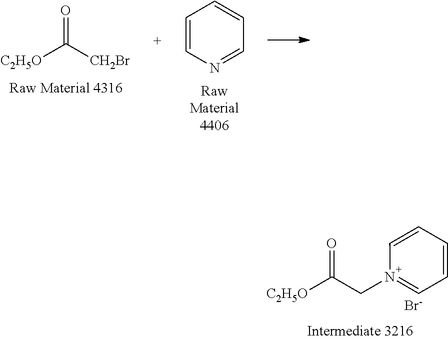

The Raw Material 4321 (0.1 mol) and the Raw Material 4406 (160 mL) are put into a three-necked flask and stirred at room temperature for 4 hours. After the completion of the reaction, 160 mL of ether is added to separate out solids, then stirring is continued for 1 hour. The solids separated out are filtered out by suction and washed with ether, and then the solids are beaten with ether, filtered out by suction, and desiccated to obtain a bright yellow solid with a yield of 87%.

### EXAMPLE 56

### Synthetizing Intermediate 3316

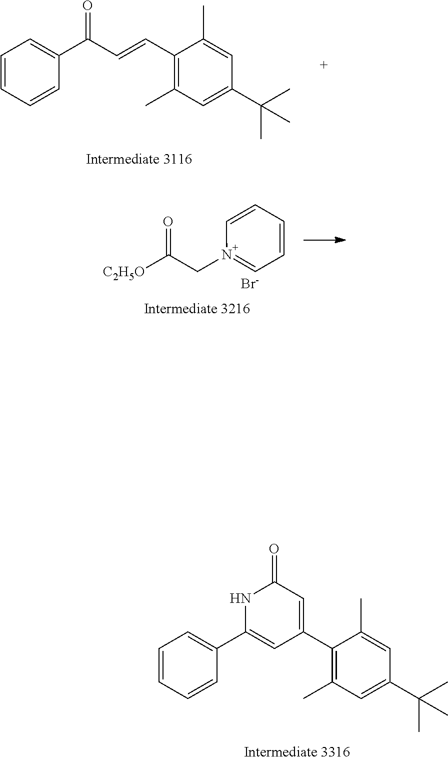

The Intermediate 3116 (70 mmol), the Intermediate 3216 (70 mmol), ammonium acetate (0.56 mol) and methanol (150 mL) are put into a round-bottom flask, refluxed and stirred at 100° C. for 12 hours. After the completion of the reaction, the reaction liquid is poured into 200 mL of water to separate out solids, the precipitate of which is filtered out by suction, washed with water, then is eluted with methanol. The solids are beaten with methanol, then filtered out by suction and desiccated to obtain a white solid with a yield of 60% and purity of 96%.

### EXAMPLE 57

### Synthetizing Intermediate 3416

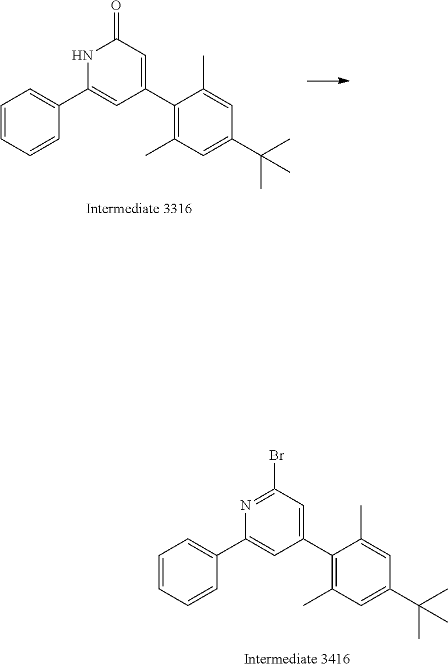 [SMILES: Cc1cc(C(C)(C)C)cc(C)c1-c1cc(-c2ccccc2)[nH]c(=O)c1 ; Cc1cc(C(C)(C)C)cc(C)c1-c1cc(Br)nc(-c2ccccc2)c1]

The Intermediate 3316 (40 mmol), P₂O₅ (120 mmol), tetrabutylammonium bromide (60 mmol), and chlorobenzene (150 mL) are put into a round-bottom flask, refluxed and stirred at 140° C. for 10 hours. After the completion of the reaction, the chlorobenzene is evaporated out under reduced pressure, and 100 mL of water is poured into the mixture, which is extracted with dichloromethane (3×80 mL), then an organic phase is collected to evaporate out a solvent under reduced pressure after being desiccated, beaten with methanol to obtain a white solid with a yield of 63% and purity of 98% by suction filtration and desiccation.

### EXAMPLE 58

### Synthetizing Intermediate 3516

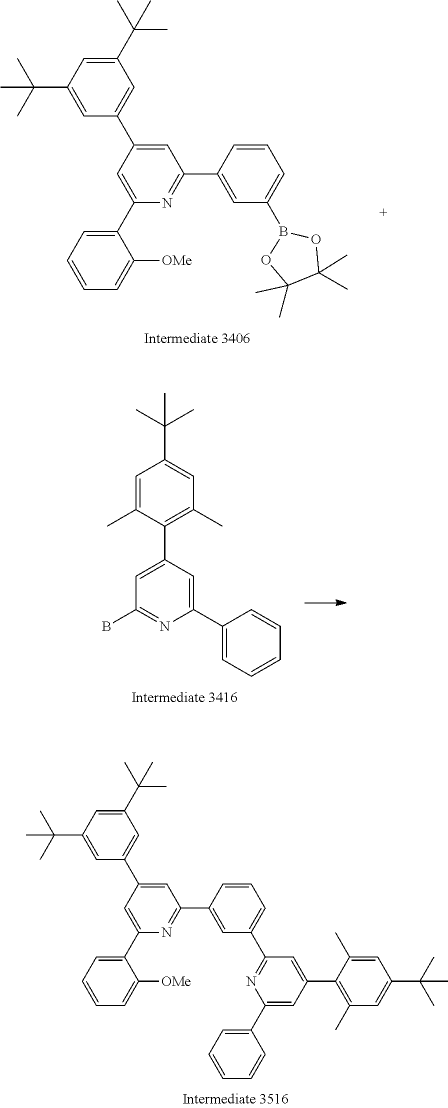

The Intermediate 3406 (10 mmol), the Intermediate 3416 (11 mmol), Pd(PPh₃)₄ (1 mmol), potassium carbonate (25 mmol), dioxane (80 mL), and water (15 mL) are put into a three-necked flask, heated to 110° C. under a nitrogen atmosphere, and react for 10 hours. After the completion of the reaction, an organic solvent is evaporated out under reduced pressure, then a remaining inorganic liquid is extracted with dichloromethane (3×50 mL),the mixture is purified by silica gel column chromatography, further beaten with methanol to obtain a white solid with a yield of 71% and purity of 99.6% by suction filtration and desiccation.

### EXAMPLE 59

### Synthetizing Ligand 2016

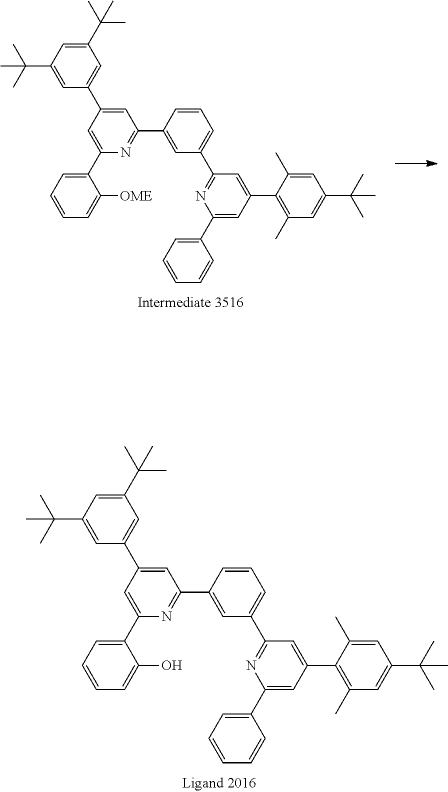

The Intermediate 3516 (7 mmol) and pyridine hydrochloride (50 g) are put into a round-bottom flask, heated to 195° C. under a nitrogen atmosphere until melt-out and stirred for 6 hours, After the completion of the reaction, the mixture is cooled to room temperature, and further added with moderate pure water with being stirred evenly, after filtering out an insoluble substance by suction, then the mixture is washed with pure water, after being separated by short silica gel column chromatography, is further recrystallized in a dichloromethane-methanol solvent system and filtered out by suction to obtain a yellow solid with a yield of 80% and purity of 99.9%.

### EXAMPLE 60

### Synthetizing Complex 1016

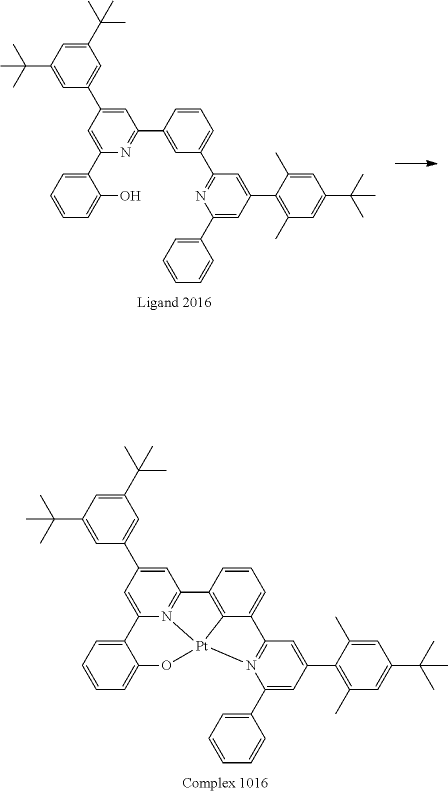

A round-bottom flask is filled with the Ligand 2016 (5 mmol), K₂PtCl₄ (6 mmol), glacial acetic acid (100 mL), and tetrabutylammonium bromide (1 mmol), and the mixture is refluxed for 20 hours under a nitrogen atmosphere. After the completion of the reaction, the reaction liquid is cooled to room temperature, added with pure water, and an orange solid is separated out. Solids are filtered out by suction and washed with pure water until the washing liquid is neutral. The solids filtered out by suction are beaten with methanol, and then separated by silica gel column chromatography, after that recrystallized in a dichloromethane-methanol solvent system to obtain an orange solid with a yield of 68% and purity of 99.8% after suction filtration and desiccation. The absorption spectrum and emission spectrum of the Complex 1016 in dichloromethane solution at room temperature are shown in FIG. 8.

### EXAMPLE 61

### Synthetizing Intermediate 3117

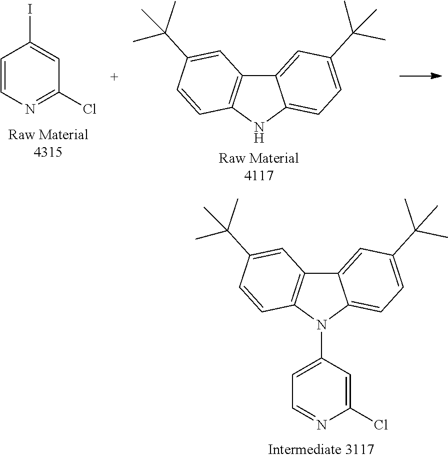 [SMILES: Clc1cc(I)ccn1 ; CC(C)(C)c1ccc2[nH]c3ccc(C(C)(C)C)cc3c2c1 ; CC(C)(C)c1ccc2c(c1)c1cc(C(C)(C)C)ccc1n2-c1ccnc(Cl)c1]

The Intermediate 4315 (30 mmol), the Raw Material 4117 (30 mmol), o-phenanthroline (4 mmol), CuI (2 mmol), potassium carbonate (60 mmol), and DMSO (100 mL) are put into a three-necked flask, heated to 120° C. under a nitrogen atmosphere and react for 10 hours. After the completion of the reaction, water is added, then a remaining inorganic liquid is extracted with dichloromethane (3×50 mL). An organic phase is collected and washed with water, after separating out the organic phase, dewatered by anhydrous magnesium sulfate, then purified by silica gel column chromatography to obtain a white solid (n-hexane:ethyl acetate=15:1) with a yield of 81% and purity of 99%.

### EXAMPLE 62

### Synthetizing Intermediate 3217

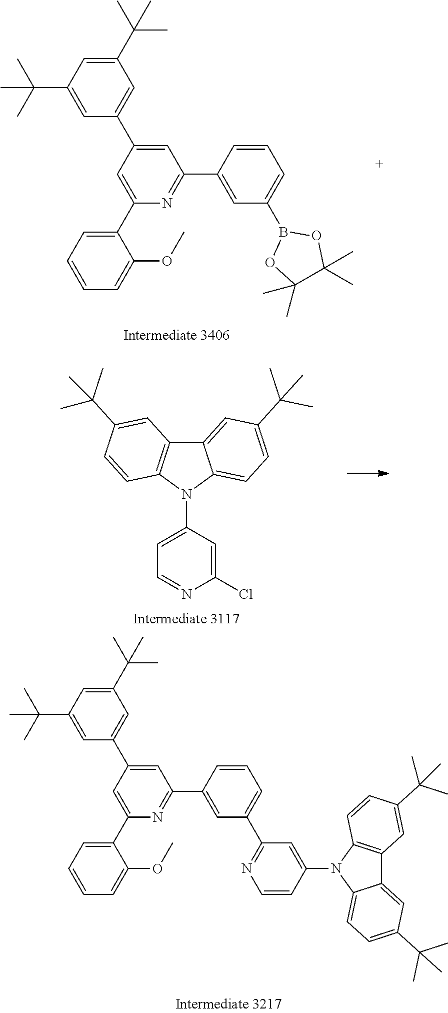

The Intermediate 3406 (10 mmol), the Intermediate 3117 (11 mmol), Pd(PPh₃)₄ (1 mmol), potassium carbonate (25 mmol), dioxane (80 mL), and water (15 mL) are put into a three-necked flask, heated to 110° C. under a nitrogen atmosphere, and react for 10 hours. After the completion of the reaction, an organic solvent is evaporated out under reduced pressure, then a remaining inorganic liquid is extracted with dichloromethane (3×50 mL), the mixture is purified by silica gel column chromatography, further beaten with methanol to obtain a white solid with a yield of 81% and purity of 99.8% by suction filtration and desiccation.

### EXAMPLE 63

### Synthetizing Ligand 2017

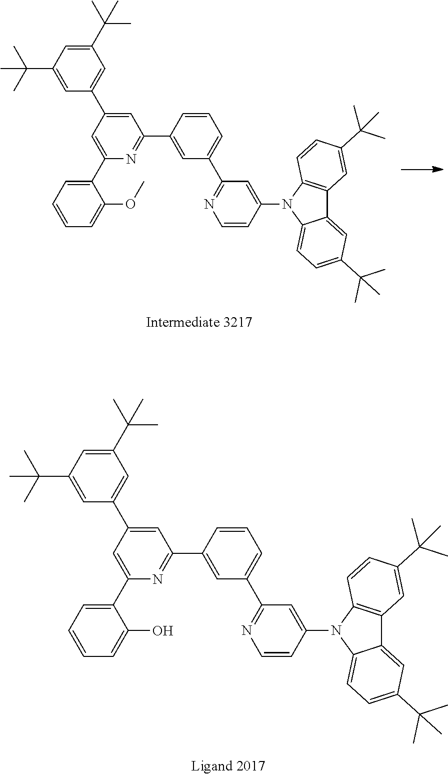

The Intermediate 3217 (8 mmol) and pyridine hydrochloride (50 g) are put into a round-bottom flask, heated to 195° C. under a nitrogen atmosphere until melt-out and stirred for 6 hours, After the completion of the reaction, the mixture is cooled to room temperature, and further added with moderate pure water with being stirred evenly, after filtering out an insoluble substance by suction, then the mixture is washed with pure water, after being separated by short silica gel column chromatography, is further recrystallized in an ethyl acetate-n-hexane solvent system and filtered out by suction to obtain a yellow solid with a yield of 80% and purity of 99.9%.

### EXAMPLE 64

### Synthetizing Complex 1017

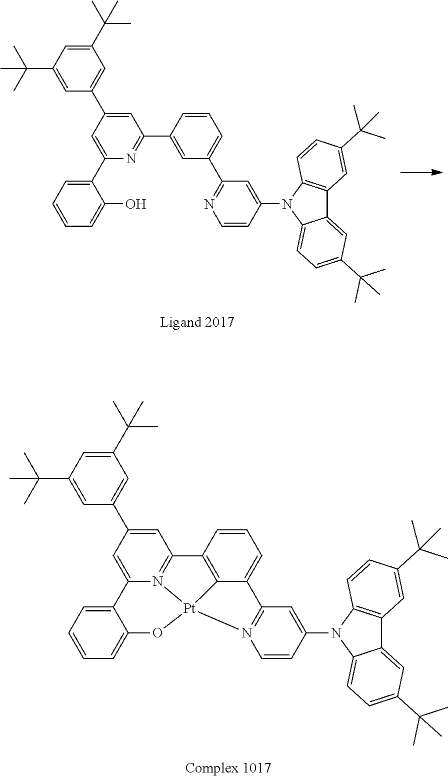

A round-bottom flask is filled with the Ligand 2017 (6 mmol), K₂PtCl₄ (7.2 mmol), glacial acetic acid (150 mL), and tetrabutylammonium bromide (1.2 mmol), and the mixture is refluxed for 20 hours under a nitrogen atmosphere. After the completion of the reaction, the reaction liquid is cooled to room temperature, added with pure water, and an orange solid is separated out. Solids are filtered out by suction and washed with pure water until the washing liquid is neutral. The solids filtered out by suction are beaten with methanol, and then separated by silica gel column chromatography, after that recrystallized in a dichloromethane-methanol solvent system to obtain an orange solid with a yield of 66% and purity of 99.9% after suction filtration and desiccation. The absorption spectrum and emission spectrum of the Complex 1017 in dichloromethane solution at room temperature are shown in FIG. 9.

### EXAMPLE 65

### Photophysical Properties of Complexes 1006, 1007, 1008, 1010, 1011, 1012, 1015, 1016 and 1017

| | | emission |
|---|---|---|
| | absorption | (dichloromethane |
| | λₘₐₓ/nm | solution) λₘₐₓ/nm |
| Complex 1006 | 285, 374, 432 | 513 |
| Complex 1007 | 289, 378, 433 | 520 |
| Complex 1008 | 284, 374, 436 | 517 |
| Complex 1010 | 288, 378, 430 | 519 |
| Complex 1011 | 242, 374, 434 | 510 |
| Complex 1012 | 286, 371, 435 | 514 |
| Complex 1015 | 285, 374, 436 | 516 |
| Complex 1016 | 281, 375, 426 | 541 |
| Complex 1017 | 291, 388, 436 | 524 |

### EXAMPLE 66

### Key Properties of the OLED Made of the Complex 1006

The simple structure of ITO/HATCN (5 nm)/TAPC (50 nm)/TCTA:Complex 1006 (10 nm)/TmPyPb (50 nm)/LiF (1.2 nm)/Al (100 nm) is adopted in such all OLEDs as display green light-emitting, and have an international color standard of (0.28, 0.65), and that the current efficiency as increases as the doping concentration of an object, reaching 109.6 cd/m² at 30 wt % doping concentration. The table shows the device performance in the luminance of 1000 cd/A:

| | | CE | PE | EQE | CIE |
|---|---|---|---|---|---|
| doping | Vₒₙ | (cd/A) | (lm/W) | (%) | (x, y) |
| concentration | (V) | at 1000 cd/A | | | |
| 10 wt % | 2.9 | 83.9 | 63.2 | 23.2 | (0.28, 0.65) |
| 20 wt % | 2.9 | 100.8 | 76.4 | 27.7 | (0.28, 0.65) |
| 30 wt % | 3.1 | 109.6 | 83.0 | 30.2 | (0.29, 0.65) |

### EXAMPLE 67

### Key Properties of the OLED Made of the Complex 1008

The simple structure of ITO/HATCN (5 nm)/TAPC (50 nm)/TCTA:Complex 1008 (10 nm)/TmPyPb (50 nm)/LiF (1.2 nm)/Al (100 nm) is adopted in such all OLEDs. The table shows the device performance in the luminance of 1000 cd/A:

| | | CE | PE | EQE | CIE |
|---|---|---|---|---|---|
| doping | Vₒₙ | (cd/A) | (lm/W) | (%) | (x, y) |
| concentration | (V) | at 1000 cd/A | | | |
| 10 wt % | 2.8 | 80.0 | 58.7 | 25.3 | (0.28, 0.65) |
| 20 wt % | 2.7 | 90.3 | 69.8 | 26.5 | (0.30, 0.64) |
| 30 wt % | 2.7 | 101.3 | 78.4 | 28.2 | (0.32, 0.63) |

### EXAMPLE 68

### Key Properties of the OLED Made of the Complex 1012

The simple structure of ITO/HATCN (5 nm)/TAPC (50 nm)/TCTA:Complex 1012 (10 nm)/TmPyPb (50 nm)/LiF (1.2 nm)/Al (100 nm) is adopted in such all OLEDs as display green light-emitting, and that the current efficiency as increases as the doping concentration of an object, reaching 102.5 cd/m² at 30 wt % doping concentration. The table shows the device performance in the luminance of 1000 cd/A:

| | | CE | PE | EQE | CIE |
|---|---|---|---|---|---|
| doping | Vₒₙ | (cd/A) | (lm/W) | (%) | (x, y) |
| concentration | (V) | at 1000 cd/A | | | |
| 10 wt % | 3.1 | 86.7 | 66.8 | 24.1 | (0.28, 0.65) |
| 20 wt % | 3.0 | 92.3 | 74.2 | 26.8 | (0.29, 0.64) |
| 30 wt % | 2.9 | 102.5 | 83.7 | 28.3 | (0.30, 0.64) |

### EXAMPLE 69

### Key Properties of the OLED Made of the Complex 1015

The simple structure of ITO/HATCN (5 nm)/TAPC (50 nm)/TCTA:Complex 1015 (10 nm)/TmPyPb (50 nm)/LiF (1.2 nm)/Al (100 nm) is adopted in such all OLEDs as display red light-emitting, and that the current efficiency as increases as the doping concentration of an object, reaching 115.1 cd/m² at 40 wt % doping concentration. The emission spectrum of electroluminescent devices with different concentrations is shown in FIG. 9. The table shows the device performance in the luminance of 1000 cd/A:

| | | CE | PE | EQE | CIE |
|---|---|---|---|---|---|
| doping | Vₒₙ | (cd/A) | (lm/W) | (%) | (x, y) |
| concentration | (V) | at 1000 cd/A | | | |
| 10 wt % | 2.9 | 98.4 | 75.8 | 26.0 | (0.29, 0.65) |
| 20 wt % | 2.9 | 100.6 | 76.9 | 26.5 | (0.30, 0.65) |
| 30 wt % | 2.8 | 109.9 | 86.9 | 28.9 | (0.30, 0.65) |
| 40 wt % | 2.8 | 115.1 | 90.5 | 30.4 | (0.31, 0.65) |

### EXAMPLE 70

### Key Properties of the OLED Made of the Complex 1017

The simple structure of ITO/HATCN (5 nm)/TAPC (50 nm)/TCTA:Complex 1017 (10 nm)/TmPyPb (50 nm)/LiF (1.2 nm)/Al (100 nm) is adopted in such all OLEDs as display green light-emitting, and that the current efficiency as increases as the doping concentration of an object, reaching 105.5 cd/m² at 30 wt % doping concentration. The emission spectrum of electroluminescent devices with different concentrations is shown in FIG. 9. The table shows the device performance in the luminance of 1000 cd/A:

| | | CE | PE | EQE | CIE |
|---|---|---|---|---|---|
| doping | Vₒₙ | (cd/A) | (lm/W) | (%) | (x, y) |
| concentration | (V) | at 1000 cd/A | | | |
| 10 wt % | 2.8 | 99.7 | 80.0 | 27.5 | (0.31, 0.64) |
| 20 wt % | 2.7 | 104.6 | 83.3 | 29.0 | (0.32, 0.63) |
| 30 wt % | 2.7 | 105.5 | 86.2 | 29.5 | (0.33, 0.63) |

### COMPARATIVE EXAMPLE 1

### Key Properties of the OLED Made of the Complex 1019 in Reference Documents

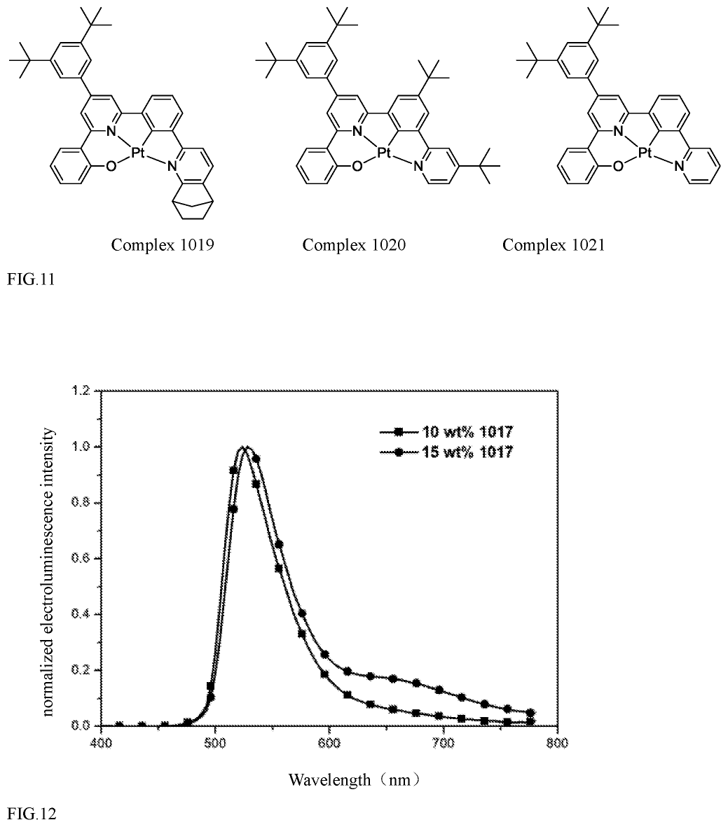

The simple structure of ITO/HATCN (5 nm)/TAPC (50 nm)/TCTA:Complex 1019 (10 nm)/TmPyPb (50 nm)/LiF (1.2 nm)/Al (100 nm) is adopted in all OLEDs. The current efficiency decreases with the increase of the guest doping concentration, and the CIE changes significantly. When the doping concentration reaches 15 wt %, the CIE has changed significantly. When the doping concentration is 20 wt %, the CIE coordinate has reached the yellow emission region. The structure of Complex 1019 in reference documents is shown in FIG. 11, and the emission spectrum of electroluminescent devices with different concentrations is shown in FIG. 12. The table shows the device performance in the luminance of 1000 cd/A:

| | | CE | PE | EQE | CIE |
|---|---|---|---|---|---|
| doping | Vₒₙ | (cd/A) | (lm/W) | (%) | (x, y) |
| concentration | (V) | at 1000 cd/A | | | |
| 10 wt % | 3.1 | 65.0 | 48.6 | 18.1 | (0.30, 0.64) |
| 15 wt % | 3.0 | 59.1 | 42.5 | 16.7 | (0.35, 0.62) |
| 20 wt % | 3.0 | 53.5 | 35.3 | 16.1 | (0.40, 0.58) |

### COMPARATIVE EXAMPLE 2

### Key Properties of the OLED Made of the Complex 1020 in Reference Documents

The simple structure of ITO/HATCN (5 nm)/TAPC (50 nm)/TCTA:Complex 1020 (10 nm)/TmPyPb (50 nm)/LiF (1.2 nm)/Al (100 nm) is adopted in all OLEDs. The current efficiency decreases with the increase of the guest doping concentration, and the CIE changes significantly. When the doping concentration reaches 15 wt %, the CIE has changed significantly. The structure of Complex 1020 in reference documents is shown in FIG. 11. The table shows the device performance in the luminance of 1000 cd/A:

| | | CE | PE | EQE | CIE |
|---|---|---|---|---|---|
| doping | Vₒₙ | (cd/A) | (lm/W) | (%) | (x, y) |
| concentration | (V) | at 1000 cd/A | | | |
| 10 wt % | 3.0 | 63.1 | 37.6 | 17.5 | (0.35, 0.61) |
| 15 wt % | 2.9 | 44.9 | 25.8 | 17.8 | (0.43, 0.56) |

### COMPARATIVE EXAMPLE 3

### Key Properties of the OLED Made of the Complex 1021 in Reference Documents

The simple structure of ITO/HATCN (5 nm)/TAPC (50 nm)/TCTA:Complex 1021 (10 nm)/TmPyPb (50 nm)/LiF (1.2 nm)/Al (100 nm) is adopted in all OLEDs. Complex 1021 has a good effect at low doping concentration (2 wt %), the current efficiency decreases with the increase of the guest doping concentration, and the CIE changes significantly. When the doping concentration reaches 15 wt %, the CIE has changed significantly. The structure of Complex 1021 in reference documents is shown in FIG. 11. The table shows the device performance in the luminance of 1000 cd/A:

| | | CE | PE | EQE | CIE |
|---|---|---|---|---|---|
| doping | Vₒₙ | (cd/A) | (lm/W) | (%) | (x, y) |
| concentration | (V) | at 1000 cd/A | | | |
| 2 wt % | 3.1 | 65.9 | 42.0 | 19.2 | (0.31, 0.61) |
| 5 wt % | 3.0 | 19.9 | 10.7 | 10.5 | (0.47, 0.51) |
| 10 wt % | 3.0 | 7.5 | 3.3 | 7.4 | (0.60, 0.39) |

Obviously, the above-mentioned examples are only to describe the content of the present invention, and are not intended to limit the embodiments. For the person skilled in the art, on the basis of the above description, other different forms of changes or modifications can be made, and it is unnecessary and impossible to give examples of all the embodiments. Obvious changes or modifications derived from this are still within the protection scope of the present invention.

Experiments show that the electroluminescent devices using a platinum (II) tetradentate ONCN complex light-emitting material of the present invention have such current efficiency in the range of 80.0-115.1 cd/A under the luminance conditions actually applied (1000 cd/m²) as is higher than 90 cd/A in the luminance of 1000 cd/m² when the doping concentration of the complex is 20 wt % in the examples, and that the emission color purity of devices changes little or even remains unchanged with the doping concentration of an object increasing. When the doping concentration of Complex 1006 is 30 wt %, the current efficiency is 109.6 cd/A; when the doping concentration of Complex 1015 is 40 wt %, the current efficiency is 115.1 cd/A. In the Comparative Example 1, where the same device structure is used, when the doping concentration of Complex 1019 is 10 wt %, the current efficiency is the highest, but only 65.0 cd/A, with the doping concentration increasing to 15 wt %, the emission has existed and excimer emission has distinctly occurred, and current efficiency has also decreased. When the doping concentration further increases to 20 wt %, the device emits yellow light and the CIE deviates distinctly. In Comparative Example 2, where the device made of Complex 1020 is used, when the doping concentration of an object is 15 wt %, excimer emission also occurs, and influences the emission color purity of devices. In Comparative Example 3, where the device made of Complex 1021 is used, it has better results only at low doping concentration, but when the doping concentration of an object reaches 5 wt %, the CIE has already deviated distinctly. Correspondingly, for the pure green platinum (II) complex (complex 1019) in the reference document (Chem. Commun., 2013, 49, 1497, U.S. Pat. No. 8,877,353, CN103097395B), the optimal result is that the maximum device efficiency is only 66.7 cd/A at the doping concentration of 13%, while its current efficiency drops to 65.1 cd/A at 1000 cd/m². In the reference document (Chem. Sci., 2014, 5, 4819; CN106795428A), by adding tert-butyl groups at different positions in the [O\hat{ }N\hat{ }C\hat{ }N] ligand, the maximum current efficiency of the platinum (II) complex can be 100.5 cd/A, but it is yellow light emission replacing pure green light emission, and yet the maximum current efficiency of the complex with green light emission is only 75 cd/A at the doping concentration of 8 wt %. In contrast, the platinum(II) tetradentate ONCN complex light-emitting material of the present invention has a simple synthesis process, and the device efficiency is significantly improved, and the color purity is better at high doping concentration and in high brightness. The doping concentration of the platinum (II) complex light-emitting material in the light-emitting layer of the electroluminescent device can maintain pure green light emission at doping concentration of 10 wt % to 40 wt %, which is more suitable for industrial manufacturing systems and commercial applications.

1. A platinum (II) tetradentate ONCN complex light-emitting material having a chemical structure of Formula I, 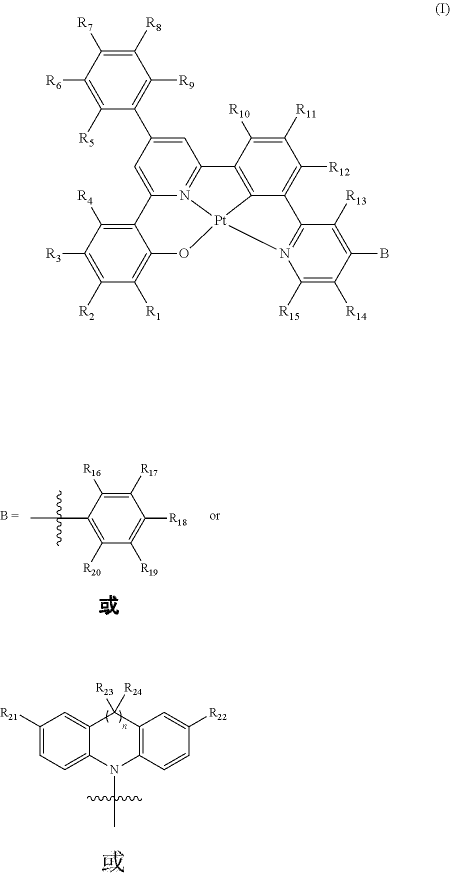
wherein R₁-R₁₅ are independently a hydrogen atom, a halogen, a hydroxyl group, an unsubstituted alkyl group, a halogenated alkyl group, a deuterated alkyl group, a cycloalkyl group, an unsubstituted aryl group, a substituted aryl group, an acyl group, an alkoxyl group, an acyloxyl group, an amino group, a nitro group, an acylamino group, an aralkyl group, a cyano group, a carboxyl group, a sulfonyl group, a styryl group, an amino carboxyl group , a carbamoyl group, an aryloxy carboxyl group, a phenoxy carboxyl or epoxy carboxyl group, a carbazole group or a diphenylamine group, and R₁-R₁₅ independently form a 5-8 membered ring with adjacent groups, and are not hydrogen at the same time; B presents an anti-aggregation group, wherein R₁₆-R₂₄ are independently a hydrogen atom, a halogen, an unsubstituted alkyl group, a halogenated alkyl group, a deuterated alkyl group, a cycloalkyl group, an unsubstituted aryl group, a substituted aryl group, a cyano group, a carbazole group, or a diphenylamine group, and n is 0 or 1.

2. The light-emitting material according to claim 1, wherein R₁-R₁₅ are independently a hydrogen atom, a halogen, a hydroxyl group, an unsubstituted alkyl group having 1 to 6 carbon atoms, a halogenated alkyl group having 1 to 6 carbon atoms, a deuterated alkyl group having 1 to 2 carbon atoms, a five- or six-membered cycloalkyl group, an unsubstituted aryl group having 6 to 10 carbon atoms, a substituted aryl group having 6 to 10 carbon atoms, an alkoxyl group having 1 to 10 carbon atoms, an amino group, a nitro group, a cyano group, a carbazolyl group, or a diphenylamine group, and independently form a 5-8 membered ring with adjacent groups, and R₁₆-R₂₄ are independently a hydrogen atom, a halogen, an unsubstituted alkyl group having 1 to 6 carbon atoms, a halogenated alkyl group having 1 to 6 carbon atoms, a five- or six-membered cycloalkyl group, an unsubstituted aryl group having 6 to 10 carbon atoms, a substituted aryl group having 6 to 10 carbon atoms, a cyano group, a carbazole group, or a diphenylamine group, and R₂₁-R₂₄ are independently a hydrogen atom, an unsubstituted alkyl group having 1 to 6 carbon atoms, or an unsubstituted aryl group having 6 to 10 carbon atoms, said halogen or halogenation includes fluorine, chlorine, or bromine.

3. The light-emitting material according to claim 2, wherein R₁-R₄ and R₁₀-R₁₂ are independently a hydrogen atom.

4. The light-emitting material according to claim 3, wherein R₅, R₇, and R₉ are independently a hydrogen atom, and R₆ and R₈ are independently a hydrogen atom, an unsubstituted alkyl group having 1 to 4 carbon atoms, a halogenated alkyl group having 1 to 4 carbon atoms, or a phenyl group, said halogen or halogenation includes fluorine, or chlorine.

5. The light-emitting material according to claim 4, wherein R₁₃-R₁₅ are independently a hydrogen atom, a halogen, an unsubstituted alkyl group having 1 to 6 carbon atoms, a halogenated alkyl group having 1 to 6 carbon atoms, a deuterated alkyl group having 1 to 2 carbon atoms, a five- or six-membered cycloalkyl group, an unsubstituted aryl group having 6 to 10 carbon atoms, or a substituted aryl group having 6 to 10 carbon atoms.

6. The light-emitting material according to claim 5, wherein R₁₃-R₁₅ are independently a hydrogen atom, an unsubstituted alkyl group having 1 to 4 carbon atoms, a trifluoromethyl group, a deuterated methyl group, or a phenyl group.

7. The light-emitting material according to claim 6, wherein R₁₇ and R₁₉ are independently a hydrogen atom, R₁₆, R₁₈ and R₂₀ are independently a hydrogen atom, a halogen, an unsubstituted alkyl group having 1 to 4 carbon atoms, a halogenated alkyl group having 1 to 4 carbon atoms, a phenyl group, a naphthyl group, or a carbazolyl group, said halogen or halogenation is fluorine.

8. The light-emitting material according to claim 7, wherein R₁₆, R₁₈ and R₂₀ are independently a hydrogen atom, an unsubstituted alkyl group having 1 to 4 carbon atoms, a halogenated alkyl group having 1 to 4 carbon atoms, a phenyl group, a naphthyl group, or a carbazolyl group; R₂₁ and R₂₂ are independently a hydrogen atom, an unsubstituted alkyl group having 1 to 4 carbon atoms, R₂₃ and R₂₄ are independently an unsubstituted alkyl group having 1 to 4 carbon atoms, or a phenyl group.

9. The light-emitting material according to claim 8 having one of the following chemical structural formulas:

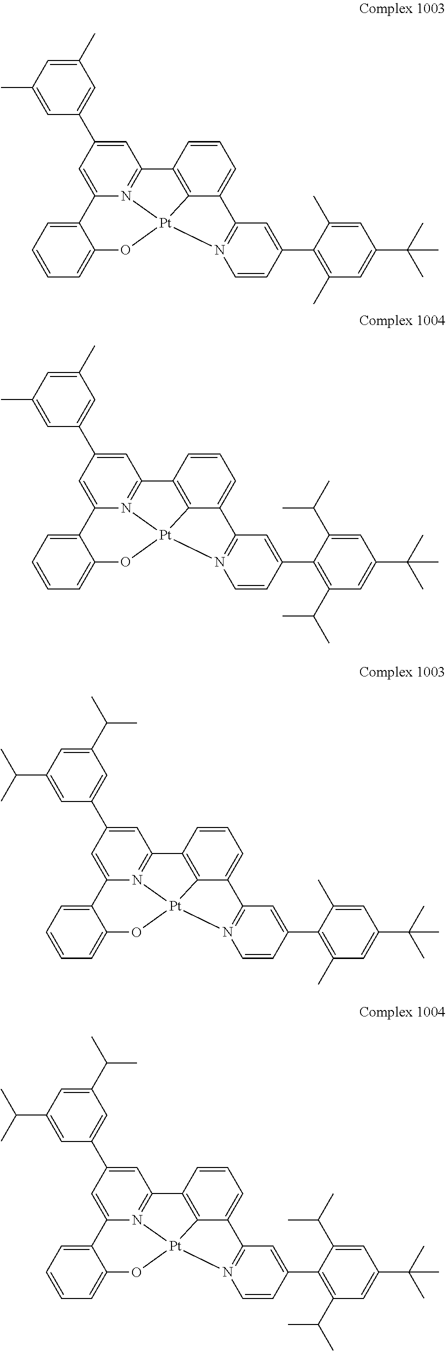

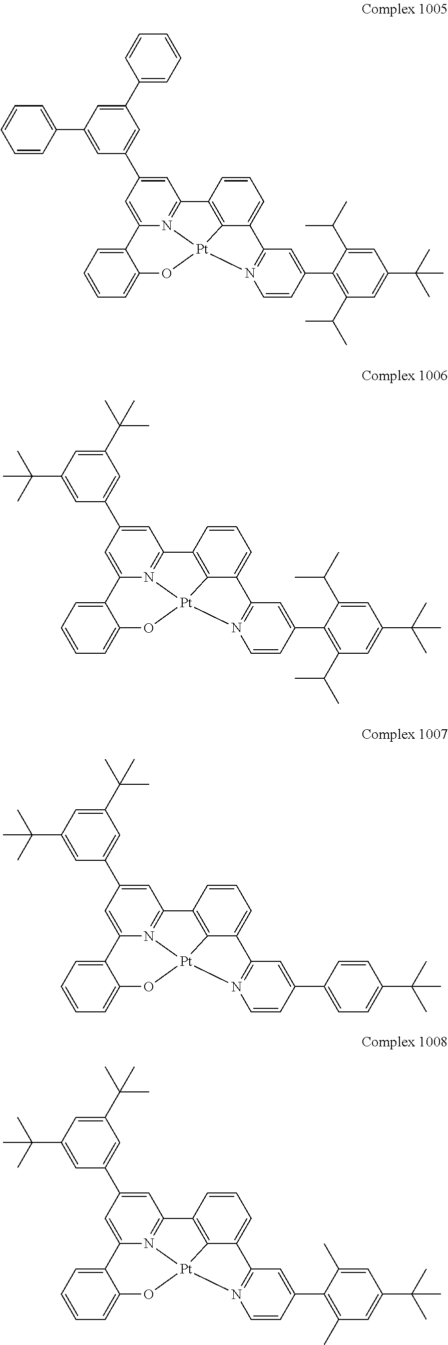

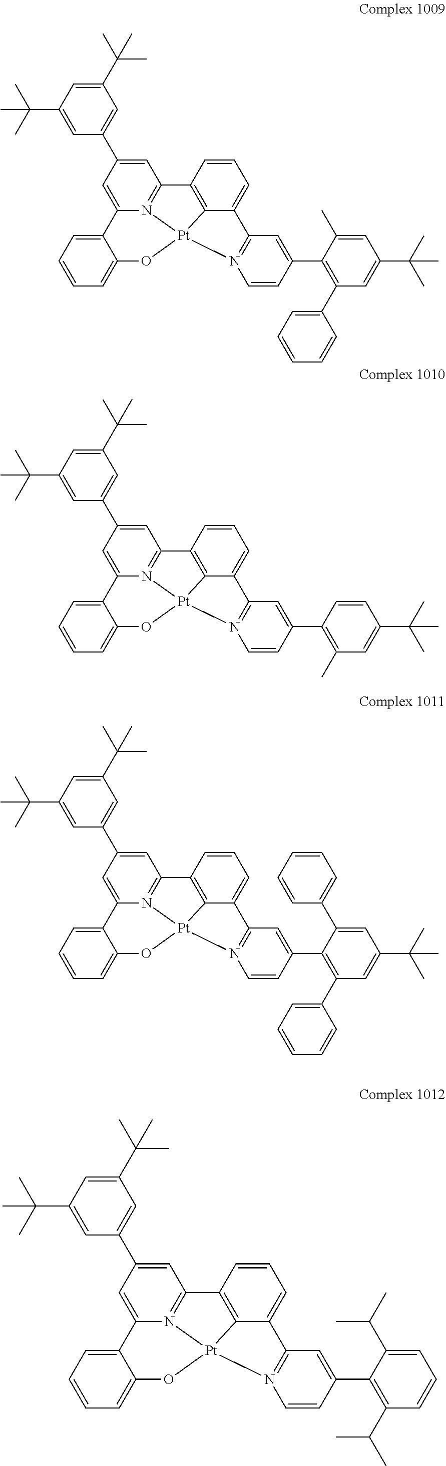

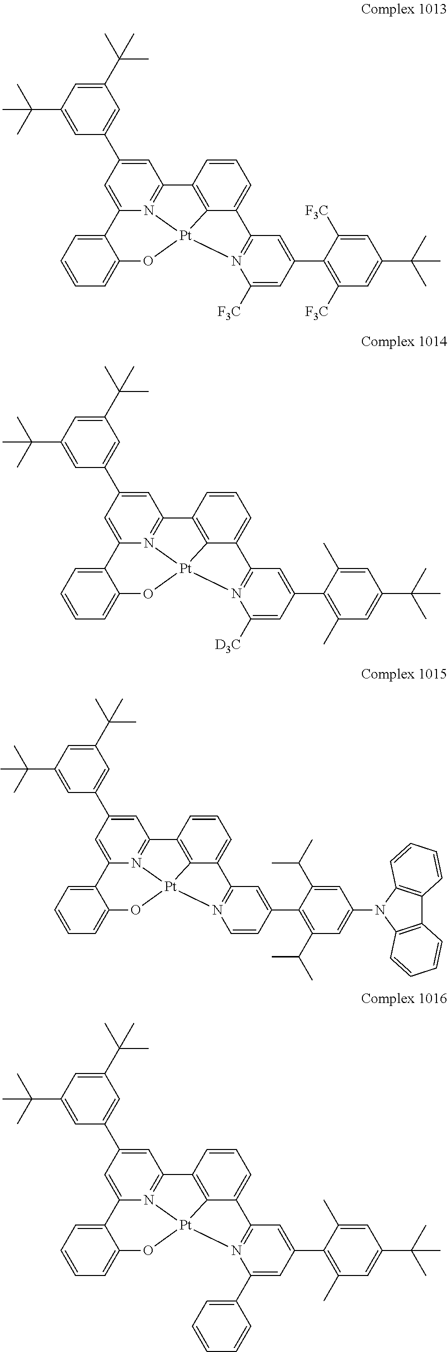

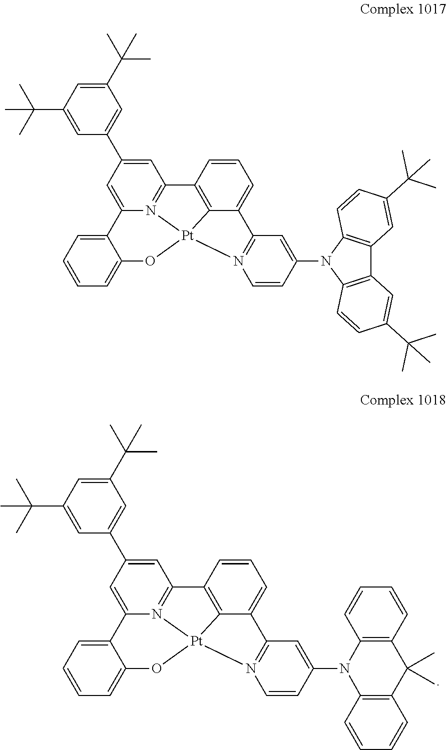

10. A preparation method for said light-emitting material according to any one of claims 1-9, comprising the following steps:
using a substituted or unsubstituted o-methoxyacetophenone compound A and a substituted or unsubstituted benzaldehyde compound B as raw materials to obtain a substituted or unsubstituted chalcone compound C under alkaline KOH conditions,
mixing a substituted or unsubstituted meta-bromoacetophenone compound D with pyridine as a solvent to obtain a pyridine salt intermediate E under iodine simple substance conditions,
obtaining a pyridine intermediate F from the substituted or unsubstituted chalcone compound C and the pyridine salt intermediate E under ammonium acetate conditions,
converting the pyridine intermediate F into a borate/boric acid intermediate G by way of functional group conversion,
coupling the boronic ester/boronic acid intermediate G with a ortho-halogen substituted pyridine compound H by way of metal coupling to obtain an intermediate I,
obtaining a ligand J from the intermediate I by way of demethylation reaction,
reacting the ligand J with a platinum compound to obtain a platinum (II) tetradentate ONCN complex light-emitting material after purification,
and the chemical equations thereof as follows:

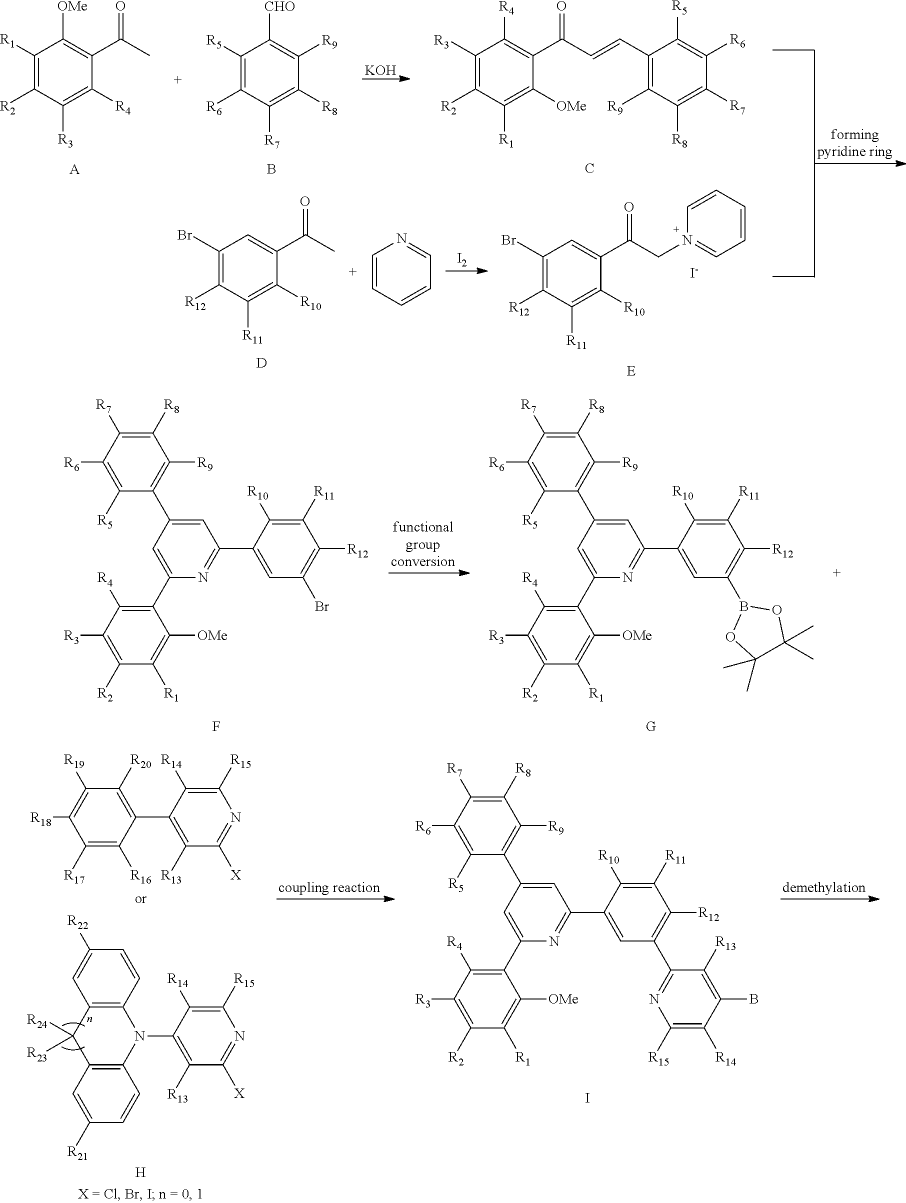

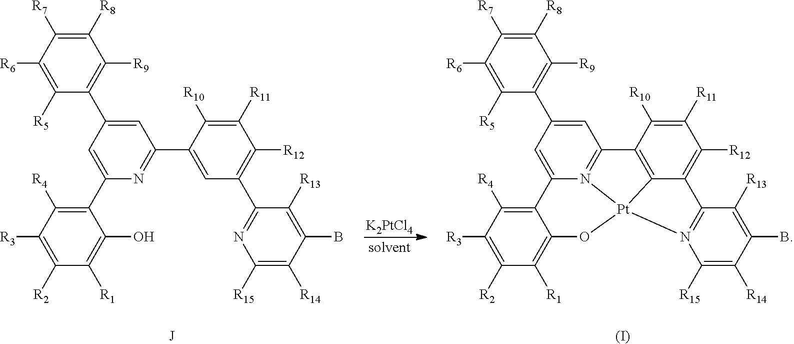

11. According to claim 10, the preparation method conditions of mentioned coupling reaction are that a coupling reaction is carried out using Pd(PPh₃)₄ as a catalyst under K₂CO₃ basic conditions.

12. The preparation method, according to claim 11, mentioned that the reaction of the ligand J with the platinum compound is a reflux reaction of the ligand J with the platinum compound and potassium tetrachloroplatinate in an acetic acid solvent.

13. A application of said light-emitting material according to any one of claims 1-9 in organic electroluminescent devices.
